(19) United States
(12) Patent Application Publication
(10) Pub. No.: US 2025/0351709 A1
(43) Pub. Date: Nov. 13, 2025

(54) DISPLAY DEVICE

(71) Applicant: Samsung Display Co., LTD., Yongin-si (KR)

(72) Inventors: Il Ha SONG, Yongin-si (KR); Hye Won CHOI, Yongin-si (KR)

(21) Appl. No.: 18/932,860

(22) Filed: Oct. 31, 2024

(30) Foreign Application Priority Data
May 7, 2024 (KR) 10-2024-0059850

(51) Int. Cl. H10K 59/80; H10K 50/13; H10K 102/00; H10K 102/20

(52) U.S. Cl. CPC H10K 59/876; H10K 50/131; H10K 59/80516; H10K 2102/20; H10K 2102/351

(57) ABSTRACT

A display device includes first to third anode electrodes on a pixel circuit layer and apart from each other, a first resonance auxiliary structure on the second anode electrode and having a first thickness, a second resonance auxiliary structure on the third anode electrode and having a second thickness, a first sub-anode electrode on the first anode electrode and in contact with the first anode electrode, a second sub-anode electrode on the second anode electrode to cover the first resonance auxiliary structure and in contact with the second anode electrode, a third sub-anode electrode on the third anode electrode to cover the second resonance auxiliary structure and in contact with the third anode electrode, a cathode electrode on the first to third anode electrodes, and an emission stack layer between the cathode electrode and the first to third sub-anode electrodes and including first to third emission layers sequentially stacked therein.

This application claims priority to, Korean Patent Application No. 10-2024-0059850, filed on May 7, 2024, and all the benefits accruing therefrom under 35 U.S.C. § 119, the content of which in its entirety is herein incorporated by reference.

### BACKGROUND

### 1. Field

Embodiments of the disclosure relate to a display device.

### 2. Description of the Related Art

An organic light emitting display device is a self-luminous display device configured to display images by using an organic light emitting diode that emits light.

Generally, an organic light emitting diode includes an anode electrode, a cathode electrode facing the anode electrode, and at least one organic emission layer disposed between the anode electrode and the cathode electrode. In such an organic light emitting diode, holes supplied from the anode electrode and electrons supplied from the cathode electrode recombine within the organic emission layer to form excitons. The organic light emitting diode generates light by using energy generated when excitons fall to a ground state.

### SUMMARY

Microcavity may be used as a method for improving light efficiency by effectively extracting light generated from an organic emission layer. Microcavity uses the principle that a strong interference effect occurs as light is repeatedly reflected by a first layer (e.g., an anode electrode) and a second layer (e.g., a cathode electrode) that are separated from each other by a preset interval. In this case, light with a specific wavelength may be amplified and light with other wavelengths may be canceled out.

Embodiments of the disclosure provide a display device using the microcavity described above.

A display device according to embodiments of the disclosure includes first to third anode electrodes disposed on a pixel circuit layer and spaced apart from each other, a first resonance auxiliary structure disposed on the second anode electrode and having a first thickness, a second resonance auxiliary structure disposed on the third anode electrode and having a second thickness greater than the first thickness, a first sub-anode electrode disposed on the first anode electrode and in electrical contact with the first anode electrode, a second sub-anode electrode disposed on the second anode electrode to cover the first resonance auxiliary structure and in electrical contact with the second anode electrode, a third sub-anode electrode disposed on the third anode electrode to cover the second resonance auxiliary structure and in electrical contact with the third anode electrode, a cathode electrode disposed on the first to third anode electrodes, and an emission stack layer disposed between the cathode electrode and the first to third sub-anode electrodes, where the emission stack layer includes a first emission layer, a second emission layer, and a third emission layer, which are sequentially stacked one on another.

In an embodiment, the first and second resonance auxiliary structures may each include an inorganic insulating material.

In an embodiment, the first to third sub-anode electrodes may each include a light transmissive metal oxide.

In an embodiment, the first emission layer may be configured to emit light in a first wavelength band, the second emission layer may emit light in a second wavelength band which is different from the first wavelength band, and the third emission layer may emit light in a third wavelength band which is different from the first and second wavelength bands.

In an embodiment, the cathode electrode may include lithium (Li)-doped silver (Ag), and the lithium (Li)-doped silver (Ag) may include greater than about 5 mass percent (mass %) and less than about 50 mass % of lithium (Li), based on a total mass of the lithium (Li)-doped silver (Ag).

In an embodiment, the display device may further include a dam structure disposed between two adjacent anode electrodes among the first to third anode electrodes.

In an embodiment, the dam structure may include a same material as materials of the first and second resonance auxiliary structures.

In an embodiment, the dam structure may be in contact with a top surface of each of the two adjacent anode electrodes.

In an embodiment, the display device may further include a first common layer disposed between the emission stack layer and the first to third sub-anode electrodes, where a portion of the first common layer on a top surface of the dam structure may be disconnected from a portion of the first common layer on a side surface of the dam structure.

In an embodiment, the emission stack layer may be continuously disposed between the cathode electrode and the first to third sub-anode electrodes.

A display device according to embodiments of the disclosure includes first and second anode electrodes disposed on a pixel circuit layer and spaced apart from each other, a first resonance auxiliary structure disposed on the second anode electrode and having a first thickness, a first sub-anode electrode disposed on the first anode electrode and in electrical contact with the first anode electrode, a second sub-anode electrode disposed on the second anode electrode to cover the first resonance auxiliary structure and in electrical contact with the second anode electrode, a cathode electrode disposed on the first and second anode electrodes, and an emission stack layer disposed between the cathode electrode and the first and second sub-anode electrodes, where the emission stack layer includes a first emission layer and a second emission layer, which are sequentially stacked one on another, and the first emission layer emits first light having a wavelength in a range of about 440 nanometers (nm) to about 480 nm.

In an embodiment, the first anode electrode may include a first reflective electrode, and a first optical distance between a top surface of the first reflective electrode and a bottom surface of the cathode electrode may be in a range of about 700 angstroms to about 800 angstroms.

In an embodiment, a first resonance distance between the top surface of the first reflective electrode and an emission center of the first emission layer may be in a range of about 250 angstroms to about 300 angstroms.

In an embodiment, the second emission layer may be configured to emit second light having a wavelength in a range of about 500 nm to about 540 nm.

In an embodiment, the first thickness may be in a range of about 150 angstroms to about 350 angstroms.

In an embodiment, the emission stack layer may further include a third emission layer disposed on the second emission layer, and the third emission layer may be configured to emit third light having a wavelength in a range of about 610 nm to about 650 nm.

In an embodiment, the display device may further include a third anode electrode disposed on the pixel circuit layer and spaced apart from the first and second anode electrodes, a second resonance auxiliary structure disposed on the third anode electrode and having a second thickness, and a third sub-anode electrode disposed on the third anode electrode to cover the second resonance auxiliary structure and in electrical contact with the third anode electrode.

In an embodiment, the second thickness may be in a range of about 400 angstroms to about 600 angstroms.

In an embodiment, the emission stack layer may be continuously disposed on the pixel circuit layer and the first and second sub-anode electrodes.

In an embodiment, the cathode electrode may include lithium (Li)-doped silver (Ag), and the lithium (Li)-doped silver (Ag) may include greater than about 5 mass % and less than about 50 mass % of lithium (Li), based on a total mass of the lithium (Li)-doped silver (Ag).

### BRIEF DESCRIPTION OF THE DRAWINGS

FIG. 1 is a block diagram showing a display device in accordance with embodiments of the disclosure.

FIG. 2 is a block diagram showing one sub-pixel among sub-pixels included in the display device of FIG. 1.

FIG. 3 is a plan view of a display panel constituting the display device of FIG. 1.

FIG. 4 is a cross-sectional view of an embodiment of the display panel of FIG. 3.

FIG. 5 is a cross-sectional view of another embodiment of the display panel of FIG. 3.

FIG. 6 is a plan view of an embodiment of one pixel among pixels included in the display panel of FIG. 3.

FIG. 7 is a cross-sectional view taken along line I1-I2 of FIG. 6.

FIG. 8 is an enlarged cross-sectional view of a region AR1 of FIG. 7.

FIGS. 9 and 10 are graphs showing the intensity of light emitted from a first emission layer as optical distances in a first sub-pixel change.

FIG. 11 is a cross-sectional view taken along line I2-I3 of FIG. 6.

FIG. 12 is an enlarged cross-sectional view of a region AR2 of FIG. 11.

FIGS. 13 and 14 are graphs showing the intensity of light emitted from a second emission layer as optical distances in a second sub-pixel change.

FIG. 15 is a cross-sectional view taken along line I3-I4 of FIG. 6.

FIG. 16 is an enlarged cross-sectional view of a region AR3 of FIG. 15.

FIGS. 17 and 18 are graphs showing the intensity of light emitted from a third emission layer as optical distances in a third sub-pixel change.

FIG. 19 is a graph showing the intensity of light emitted from a pixel including first and second resonance auxiliary structures with respect to each wavelength.

FIG. 20 is a graph showing the intensity of light emitted from a pixel not including first and second resonance auxiliary structures with respect to each wavelength.

FIG. 21 is a graph for describing light reflectance versus a lithium content in a cathode electrode.

FIG. 22 is a graph for describing light absorbance versus a lithium content in a cathode electrode.

FIGS. 23 to 28 are cross-sectional views showing an embodiment of a method of manufacturing a pixel of FIG. 6.

FIG. 29 is a block diagram showing a display system in accordance with an embodiment.

FIGS. 30 to 33 are perspective views showing application examples of the display system of FIG. 29.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. It will be understood that when a portion is referred to as being “connected to” another portion, it may be “directly connected to” the other portion or “indirectly connected to” the other portion with intervening portions therebetween.

will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. The expression “at least one of X, Y, and Z” or “at least one selected from X, Y, and Z” may be interpreted as one X, one Y, one Z, or any combination of two or more of X, Y, and Z (e.g., XYZ, XYY, YZ, ZZ, etc.). It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms such as “below,” “above,” etc. may be used for descriptive purposes, thereby describing the relationship between one element or feature and another element(s) or feature(s) as illustrated in the drawings. Spatially relative terms are intended to include different directions in use, operation, and/or manufacture, in addition to the directions depicted in the drawings. For example, when the device illustrated in the figures is turned over, elements depicted as being located “below” other elements or features are located “above” the other elements or features. Accordingly, in an embodiment, the term “below” may include both up and down directions. In addition, the device may be oriented in other directions (e.g., rotated by 90 degrees or in other orientations), and thus, the spatially relative terms as used herein should be interpreted accordingly.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

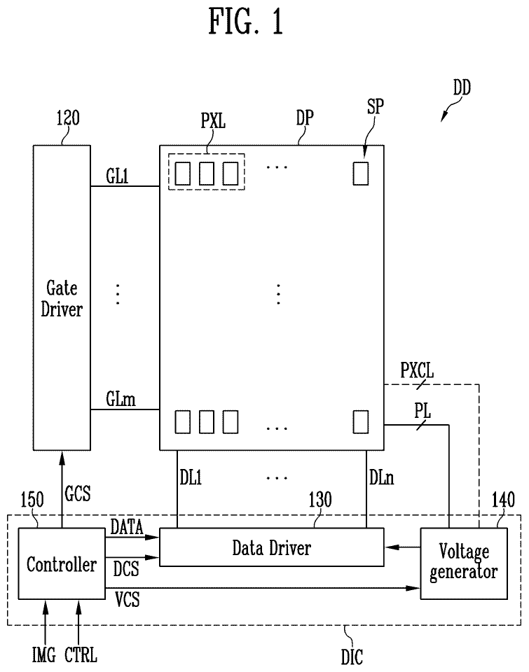

FIG. 1 is a block diagram showing a display device in accordance with embodiments of the disclosure.

Referring to FIG. 1, an embodiment of a display device DD may include a display panel DP, a gate driver 120, a data driver 130, a voltage generator 140, and a controller 150.

The display panel DP may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn. Here, n and m are natural numbers.

The sub-pixels SP may generate pieces of light of two or more colors. In an embodiment, for example, the sub-pixels SP may generate light of red, green, blue, cyan, magenta, yellow, etc.

Two or more sub-pixels among the sub-pixels SP may constitute one pixel PXL. In an embodiment, for example, the pixel PXL may include three sub-pixels as illustrated in FIG. 1. The pixel PXL may emit pieces of light of various colors and various luminances depending on a combination of pieces of light emitted from the sub-pixels included in the pixel PXL.

The gate driver 120 may be connected to the sub-pixels SP arranged in the row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating the start of each frame, a horizontal synchronization signal, etc.

The gate driver 120 may be disposed on one side of the display panel DP. However, embodiments are not limited thereto. In an embodiment, for example, the gate driver 120 may be divided into two or more physically and/or logically separated drivers. Such drivers may be disposed on one side of the display panel DP and on the other side of the display panel DP opposite to the one side. In embodiments, the gate driver 120 may be arranged around the display panel DP in various shapes in accordance with embodiments.

The data driver 130 may be connected to the sub-pixels SP arranged in the column direction through the first to n-th data lines DL1 to DLn. The data driver 130 receives image data DATA and a data control signal DCS from the controller 150. The data driver 130 operates in response to the data control signal DCS. In embodiments, the data control signal DCS may include a source start signal, a source shift clock, a source output enable signal, etc.

The data driver 130 may receive voltages from the voltage generator 140. The data driver 130 may apply, to the first to n-th data lines DL1 to DLn, data signals having gray scale voltages corresponding to the image data DATA by using the received voltages. When the gate signal is applied to each of the first to m-th gate lines GL1 to GLm, the data signals corresponding to the image data DATA may be applied to the data lines DL1 to DLn. Accordingly, the sub-pixels SP may generate light corresponding to the data signals, and the display panel DP may display an image.

In embodiments, the gate driver 120 and the data driver 130 may include complementary metal-oxide semiconductor (CMOS) circuit elements.

The voltage generator 140 may operate in response to a voltage control signal VCS from controller 150. The voltage generator 140 may be configured to generate a plurality of voltages and provide the generated voltages to components of the display device DD, such as the gate driver 120, the data driver 130, and the controller 150. The voltage generator 140 may generate a plurality of voltages by receiving an input voltage from the outside of the display device DD and regulating the received voltages.

The voltage generator 140 may generate a first power supply voltage and a second power supply voltage. In an embodiment, the generated first and second power supply voltages may be provided to the sub-pixels SP through the power lines PL. In another embodiment, at least one of the first and second power supply voltages may be provided from the outside of the display device DD.

In embodiments, the voltage generator 140 may provide various voltages and/or signals. In an embodiment, for example, the voltage generator 140 may provide one or more initialization voltages to be applied to the sub-pixels SP. In an embodiment, for example, during a sensing operation of sensing electrical characteristics of the transistors and/or light emitting devices of the sub-pixels SP, a certain reference voltage may be applied to the first to n-th data lines DL1 to DLn, and the voltage generator 140 may generate the reference voltage and transmit the generated reference voltage to the data driver 130. In an embodiment, for example, during a display operation of displaying an image on the display panel DP, common pixel control signals may be applied to the sub-pixels SP, and the voltage generator 140 may generate the pixel control signals. In embodiments, the voltage generator 140 may provide pixel control signals to the sub-pixels SP through pixel control lines PXCL. In an embodiment, as shown in FIG. 1, the pixel control lines PXCL may be connected between the voltage generator 140 and the display panel DP, but embodiments are not limited thereto. In another embodiment, for example, the pixel control lines PXCL may be connected between the gate driver 120 and the display panel DP. In such an embodiment, the pixel control signals may be transmitted from the voltage generator 140 to the pixel control lines PXCL through the gate driver 120.

The controller 150 may control overall operations of the display device DD. The controller 150 may receive input image data IMG and a corresponding control signal CTRL from the outside. The controller 150 may provide the gate control signal GCS, the data control signal DCS, and the voltage control signal VCS in response to the control signal CTRL.

The controller 150 may convert the input image data IMG into image data DATA suitable for the display device DD or the display panel DP and output the image data DATA. In embodiments, the controller 150 may output the image data DATA by aligning the input image data IMG so as to be suitable for the sub-pixels SP in units of rows.

Two or more components of the data driver 130, the voltage generator 140, and the controller 150 may be mounted on one integrated circuit. In an embodiment, as illustrated in FIG. 1, the data driver 130, the voltage generator 140, and the controller 150 may be included in a driver integrated circuit DIC. In such an embodiment, the data driver 130, the voltage generator 140, and the controller 150 may be functionally separate components within one driver integrated circuit DIC. In other embodiments, at least one selected from the data driver 130, the voltage generator 140, and the controller 150 may be provided as a component separate from the driver integrated circuit DIC.

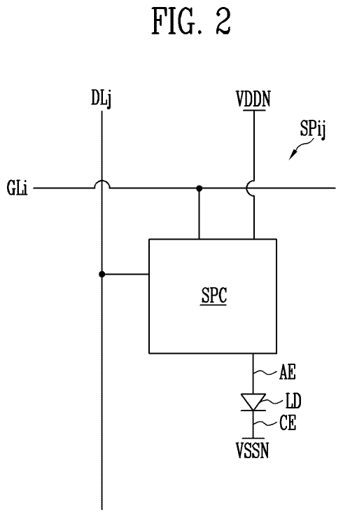

FIG. 2 is a block diagram showing one sub-pixel among sub-pixels included in the display device of FIG. 1. FIG. 2 illustrates a sub-pixel SPij arranged in an i-th row (where i is an integer greater than or equal to 1 and less than or equal to m) and a j-th column (where j is an integer greater than or equal to 1 and less than or equal to n) among the sub-pixels SP of FIG. 1.

Referring to FIG. 2, an embodiment of the sub-pixel SPij may include a sub-pixel circuit SPC and a light emitting device LD.

The light emitting device LD may be connected between a first power supply voltage node VDDN and a second power supply voltage node VSSN. The first power supply voltage node VDDN may be connected to one of the power lines PL of FIG. 1 and receive the first power supply voltage. The second power supply voltage node VSSN may be connected to another one of the power lines PL of FIG. 1 and receive the second power supply voltage. The first power supply voltage may have a higher voltage level than the second power supply voltage.

The light emitting device LD may be connected between an anode electrode AE and a cathode electrode CE. The anode electrode AE may be connected to the first power supply voltage node VDDN through the sub-pixel circuit SPC. In an embodiment, for example, the anode electrode AE may be connected to the first power supply voltage node VDDN through one or more transistors included in the sub-pixel circuit SPC. The cathode electrode CE may be connected to the second power supply voltage node VSSN. The light emitting device LD is configured to emit light according to a current flowing from the anode electrode AE to the cathode electrode CE.

The sub-pixel circuit SPC may be connected to an i-th gate line GLi among the first to m-th gate lines GL1 to GLm of FIG. 1 and a j-th data line DLj among the first to n-th data lines DL1 to DLn of FIG. 1. In response to the gate signal received through the i-th gate line GLi, the sub-pixel circuit SPC may control the light emitting device LD to emit light corresponding to the data signal received through the j-th data line DLj. In embodiments, the sub-pixel circuit SPC may be further connected to the pixel control lines PXCL of FIG. 1. In such embodiments, the sub-pixel circuit SPC may control the light emitting device LD in further response to pixel control signals received through the pixel control lines PXCL.

For these operations, the sub-pixel circuit SPC may include circuit elements, such as transistors and one or more capacitors.

The transistors of the sub-pixel circuit SPC may include P-type transistors and/or N-type transistors. In embodiments, the transistors of the sub-pixel circuit SPC may include a metal oxide semiconductor field effect transistor (MOSFET). In embodiments, the transistors of the sub-pixel circuit SPC may include at least one selected from an amorphous silicon semiconductor, a monocrystalline silicon semiconductor, a polycrystalline silicon semiconductor and an oxide semiconductor, for example.

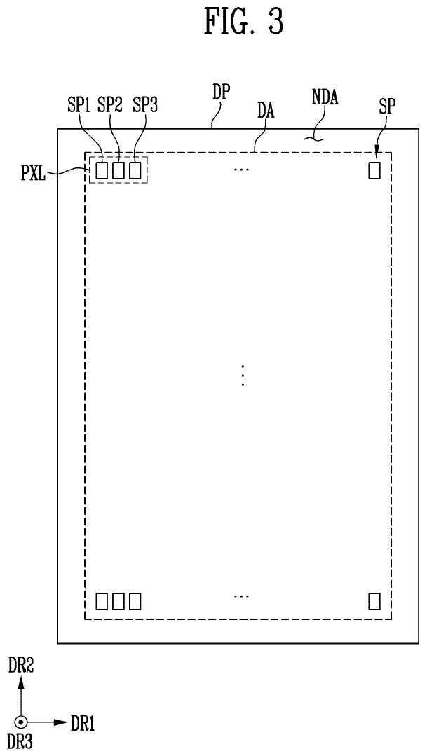

FIG. 3 is a plan view of a display panel constituting the display device of FIG. 1.

Referring to FIG. 3, an embodiment of the display panel DP may include a display area DA and a non-display area NDA. The display panel DP may display an image through the display area DA. The non-display area NDA may be disposed around the display area DA.

The display panel DP may include sub-pixels SP disposed in the display area DA. The sub-pixels SP may be disposed (or arranged) in a first direction DR1 and a second direction DR2 crossing the first direction DR1. In an embodiment, for example, the sub-pixels SP may be disposed in a matrix form in the first direction DR1 and the second direction DR2. In another embodiment, for example, the sub-pixels SP may be disposed in a zigzag form in the first direction DR1 and the second direction DR2. The arrangement of the sub-pixels SP may vary depending on embodiments. The first direction DR1 may be a row direction and the second direction DR2 may be a column direction.

Two or more sub-pixels among the sub-pixels SP may constitute one pixel PXL. In an embodiment, as shown in FIG. 3, the pixel PXL may include three sub-pixels SP1, SP2, and SP3, but embodiments are not limited thereto. In another embodiment, for example, the pixel PXL may include two sub-pixels. Hereinafter, for convenience of description, embodiments where the pixel PXL includes first to third sub-pixels SP1, SP2, and SP3 will be mainly described.

Each of the first to third sub-pixels SP1, SP2, and SP3 may include at least one light emitting device (see LD of FIG. 2) and a sub-pixel circuit (see SPC of FIG. 2) configured to generate light. In an embodiment, for example, the light emitting devices of the first to third sub-pixels SP1, SP2, and SP3 may generate blue, green, and/or red light.

Components for controlling the sub-pixels SP may be disposed in the non-display area NDA, in which no subpixel is disposed. Lines connected to the sub-pixels SP, for example, the first to m-th gate lines GL1 to GLm, the first to n-th data lines DL1 to DLn, and the power lines PL, and the pixel control lines PXCL in FIG. 1 may be disposed in the non-display area NDA.

At least one selected from the gate driver 120, the data driver 130, the voltage generator 140, and the controller 150 of FIG. 1 may be disposed in the non-display area NDA of the display panel DP. In embodiments, the gate driver 120 may be disposed in the non-display area NDA. In such embodiments, the data driver 130, the voltage generator 140, and the controller 150 may be implemented as the driver integrated circuit DIC of FIG. 1, and the driver integrated circuit DIC may be connected to the lines disposed in the non-display area NDA. In other embodiments, the gate driver 120 may be implemented as a single integrated circuit separate from the display panel DP along with the data driver 130, the voltage generator 140, and the controller 150.

In embodiments, the display area DA may have various shapes. The display area DA may have a closed loop shape including straight and/or curved sides. In an embodiment, for example, the display area DA may have one of various shapes such as a polygonal shape, a circular shape, a semicircular shape, or an elliptical shape.

In embodiments, the display panel DP may have a flat display surface. In other embodiments, the display panel DP may have a display surface that is at least partially round. In embodiments, the display panel DP may be bendable, foldable, or rollable. In such embodiments, the substrate of the display panel DP and/or display panel DP may include a material with flexible properties.

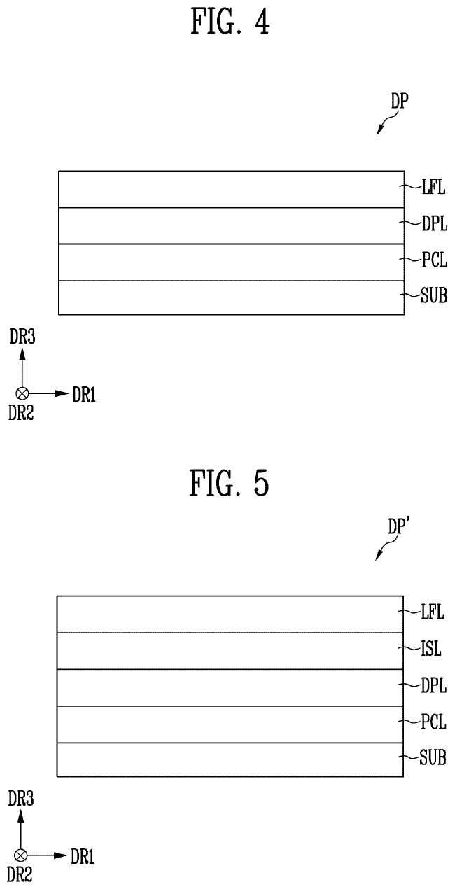

FIG. 4 is a cross-sectional view of an embodiment of the display panel of FIG. 3.

Referring to FIG. 4, an embodiment of the display panel DP may include a substrate SUB, and a pixel circuit layer PCL, a display element layer DPL, and a light functional layer LFL, which are sequentially stacked on the substrate SUB in a third direction DR3 crossing the first and second directions DR1 and DR2. Here, the third direction DR3 may be a thickness direction of the display panel DP or the substrate SUB.

The substrate SUB may include an insulating material such as glass or resin. In an embodiment, for example, the substrate SUB may include a glass substrate. In another embodiment, for example, the substrate SUB may include a polyimide (PI) substrate. In another embodiment, for example, the substrate SUB may include a silicon wafer substrate formed by using a semiconductor process.

In embodiments, the substrate SUB may include a flexible material to be bendable or foldable, and may have a single-layer structure or a multilayer structure. In an embodiment, for example, the flexible material may include at least one selected from polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL may be disposed on the substrate SUB. The pixel circuit layer PCL may include insulating layers, and semiconductor patterns and conductive patterns disposed between the insulating layers. The conductive patterns of the pixel circuit layer PCL may function as or define circuit elements, lines, etc.

The circuit elements of the pixel circuit layer PCL may form the sub-pixel circuits SPC of the sub-pixels SP of FIG. 3. In other words, the circuit elements of the pixel circuit layer PCL may be provided as transistors and one or more capacitors of the sub-pixel circuit SPC.

The lines of the pixel circuit layer PCL may include lines connected to the sub-pixels SP. The lines of the pixel circuit layer PCL may include various signal lines and/or voltage lines used to drive the display element layer DPL.

The display element layer DPL may be disposed on the pixel circuit layer PCL. The display element layer DPL may include light emitting devices of the sub-pixels SP.

The light functional layer LFL may be disposed on the display element layer DPL. The light functional layer LFL may include light conversion patterns having color conversion particles and/or scattering particles. In an embodiment, for example, the color converting particles may include quantum dots. The quantum dots may change the wavelength (or color) of light emitted from the display element layer DPL. The light functional layer LFL may further include light scattering patterns with scattering particles. In embodiments, the light conversion patterns and the light scattering patterns may be omitted.

The light functional layer LFL may further include a color filter layer including color filters. The color filter may selectively transmit light of a specific wavelength (or a specific color). In other embodiments, the color filter layer may be omitted.

A window (not shown) may be provided on the light functional layer LFL to protect the exposed surface (or the top surface) of the display panel DP. The window may protect the display panel DP from external impact. The window may be coupled to the light functional layer LFL through an optically clear adhesive member. The window may have a multilayer structure selected from a glass substrate, a plastic film, and a plastic substrate. The multilayer structure may be formed through a continuous process or an adhesion process using an adhesive layer. All or a part of the window may be flexible.

FIG. 5 is a cross-sectional view of another embodiment of the display panel of FIG. 3.

Referring to FIG. 5, an embodiment of a display panel DP′ may include a substrate SUB, a pixel circuit layer PCL, a display element layer DPL, an input sensing layer ISL, and a light functional layer LFL. The substrate SUB, the pixel circuit layer PCL, the display element layer DPL, and the light functional layer LFL may be configured to be substantially the same as (or similar to) the substrate SUB, pixel circuit layer PCL, the display element layer DPL, and the light functional layer LFL, which have been described with reference to FIG. 4. Therefore, any repetitive detailed descriptions thereof will be omitted.

The input sensing layer ISL may detect a user input on the top surface (or the display surface) of the display panel DP′. The input sensing layer ISL may include components suitable for detecting external objects such as the user's hand, pen, etc. In an embodiment, for example, the input sensing layer ISL may include touch electrodes.

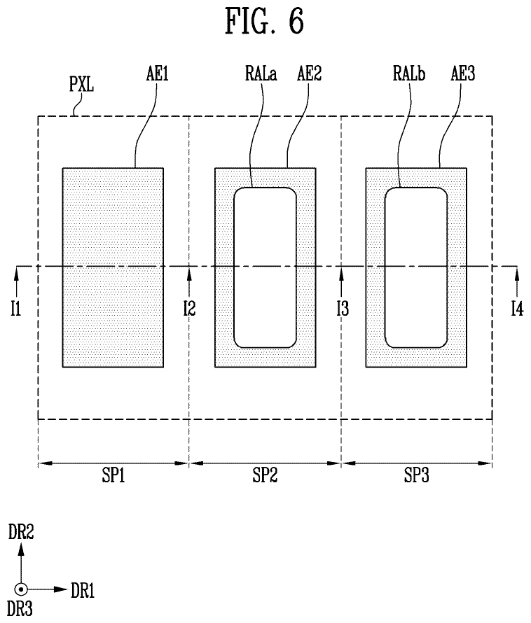

FIG. 6 is a plan view of an embodiment of one pixel among pixels included in the display panel of FIG. 3.

Referring to FIG. 6, in an embodiment, the pixel PXL may include first to third sub-pixels SP1, SP2, and SP3. In an embodiment, the first to third sub-pixels SP1, SP2, and SP3 may be disposed or arranged in the first direction DR1. However, the arrangement of the first to third sub-pixels SP1, SP2, and SP3 is not limited thereto and may vary depending on embodiments. In another embodiment, for example, the first to third sub-pixels SP1, SP2, and SP3 may be arranged in a zigzag form.

First to third anode electrodes AE1, AE2, and AE3 may be disposed in the first to third sub-pixels SP1, SP2, and SP3, respectively. The first anode electrode AE1 may serve as an anode electrode (see AE of FIG. 2) connected to the sub-pixel circuit (see SPC of FIG. 2) of the first sub-pixel SP1. The second anode electrode AE2 may serve as an anode electrode (see AE of FIG. 2) connected to the sub-pixel circuit (see SPC of FIG. 2) of the second sub-pixel SP2. The third anode electrode AE3 may serve as an anode electrode (see AE of FIG. 3) connected to the sub-pixel circuit (see SPC of FIG. 3) of the third sub-pixel SP3.

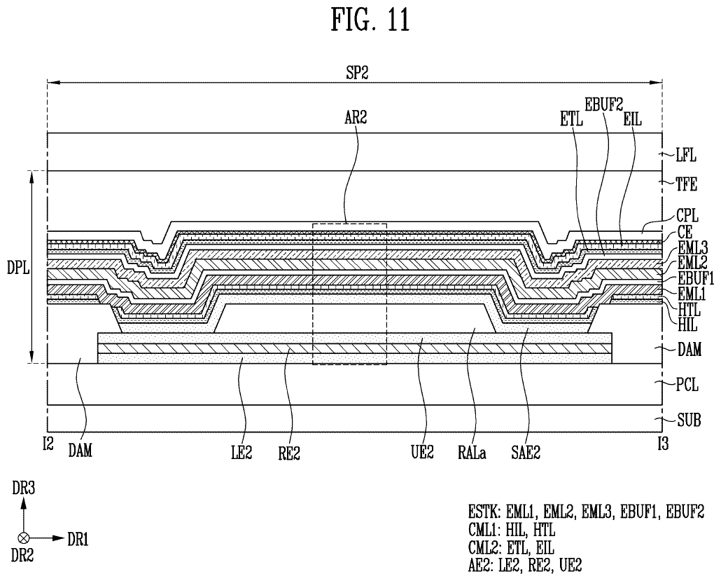

A first resonance auxiliary structure RALa may be disposed on the second anode electrode AE2. The first resonance auxiliary structure RALa may completely overlap a portion of the second anode electrode AE2 in a plan view or when viewed in the third direction DR3. The first resonance auxiliary structure RALa may serve to improve the light efficiency of the pixel PXL by inducing microcavity of light of a specific wavelength. This will be described later in greater detail with reference to FIGS. 11 to 14.

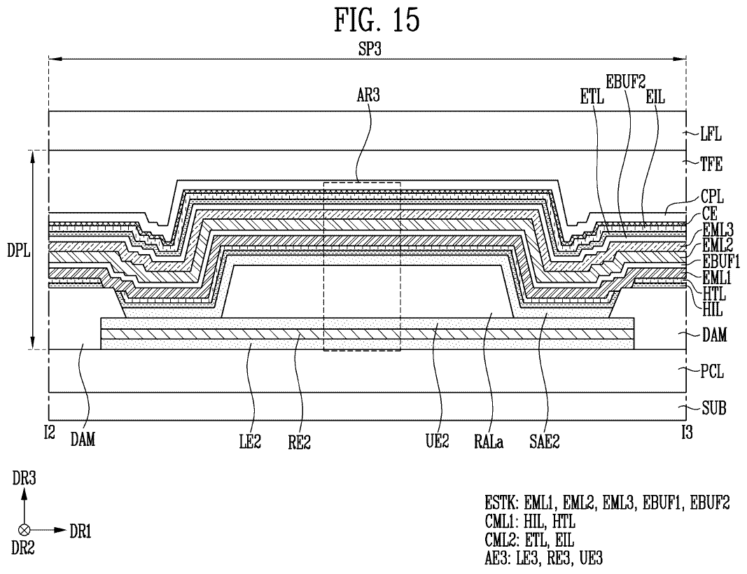

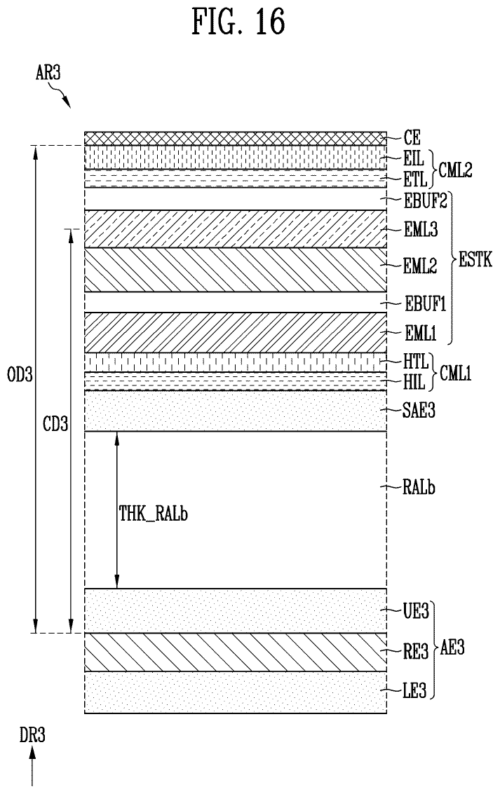

A second resonance auxiliary structure RALb may be disposed on the third anode electrode AE3. The second resonance auxiliary structure RALb may completely overlap a portion of the third anode electrode AE3 in a plan view. The second resonance auxiliary structure RALb may serve to improve the light efficiency of the pixel PXL by inducing microcavity of light of a specific wavelength. This will be described later in greater detail with reference to FIGS. 15 to 18.

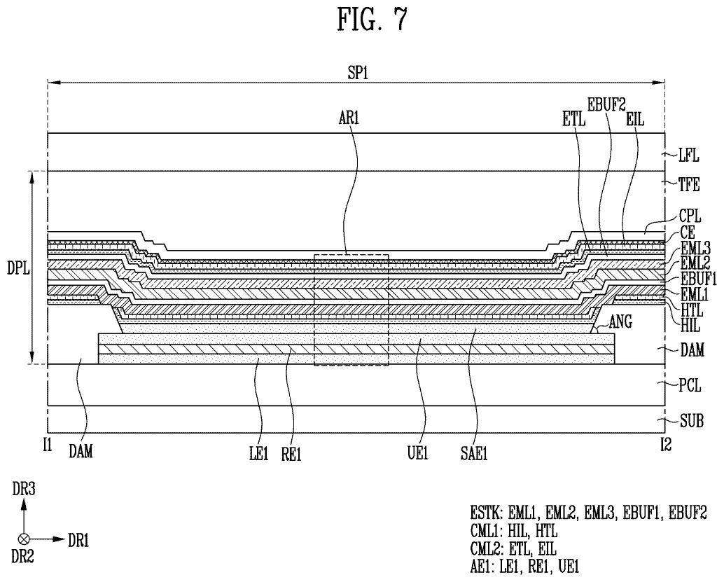

FIG. 7 is a cross-sectional view taken along line I1-I2 of FIG. 6. FIG. 7 is a cross-sectional view showing the first sub-pixel of FIG. 6.

Referring to FIGS. 6 and 7, in an embodiment, the pixel circuit layer PCL, the display element layer DPL, and the light functional layer LFL may be sequentially disposed on the substrate SUB.

The pixel circuit layer PCL may include insulating layers, semiconductor patterns, and conductive patterns, which are stacked on the substrate SUB. The semiconductor patterns and the conductive patterns may be disposed between the insulating layers. The conductive patterns may include, for example, at least one selected from copper (Cu), molybdenum (Mo), tungsten (W), aluminum neodymium (AlNd), titanium (Ti), aluminum (AI), and silver (Ag).

The sub-pixel circuit (see SPC of FIG. 2) of the first sub-pixel SP1 may include transistors and one or more capacitors. The semiconductor patterns and the conductive patterns of the pixel circuit layer PCL may function as transistors and capacitors of the sub-pixel circuit SPC. In addition, the conductive patterns of the pixel circuit layer PCL may also function as (or define), for example, the first to m-th gate lines GL1 to GLm, the first to n-th data lines DL1 to DLn, and the power lines PL, and the pixel control lines PXCL in FIG. 1.

The display element layer DPL may be disposed on the pixel circuit layer PCL. The display element layer DPL may include a first anode electrode AE1, a first sub-anode electrode SAE1, a dam structure DAM, a first common layer CML1, an emission stack layer ESTK, a second common layer CML2, a cathode electrode CE, a capping layer CPL, and an encapsulation layer TFE.

The first anode electrode AE1 may be disposed on the pixel circuit layer PCL. The first anode electrode AE1 may be electrically connected to at least one transistor among the transistors constituting the sub-pixel circuit SPC of the first sub-pixel SP1.

The first anode electrode AE1 may include a first lower transparent electrode LE1, a first reflective electrode RE1, and a first upper transparent electrode UE1, which are sequentially stacked one on another in the third direction DR3.

The first lower transparent electrode LE1 and the first upper transparent electrode UE1 may be configured to be substantially transparent or translucent to satisfy certain light transmittance. In an embodiment, for example, the first lower transparent electrode LE1 and the first upper transparent electrode UE1 may each include a light-transmissive metal oxide. In an embodiment, for example, the first lower transparent electrode LE1 and the first upper transparent electrode UE1 may each include at least one selected from indium tin oxide (ITO), indium zinc oxide (IZO), zinc oxide (ZnO), indium gallium zinc oxide (IGZO), and indium tin zinc oxide (ITZO). However, the materials of the first lower transparent electrode LE1 and the first upper transparent electrode UE1 are not limited thereto.

The first reflective electrode RE1 may include a conductive material having a certain reflectance. In an embodiment, for example, the first reflective electrode RE1 may include an opaque metal. The opaque metal may include at least one selected from silver (Ag), magnesium (Mg), aluminum (AI), platinum (Pt), palladium (Pd), gold (Au), nickel (Ni), neodymium (Nd), iridium (Ir), chromium (Cr), titanium (Ti), and any alloy thereof. However, the material of the first reflective electrode RE1 is not limited thereto.

The first sub-anode electrode SAE1 may be disposed on the first upper transparent electrode UE1. The first sub-anode electrode SAE1 may be in direct contact with the first upper transparent electrode UE1. The first sub-anode electrode SAE1 may be configured to be substantially transparent or translucent to satisfy certain light transmittance. In an embodiment, for example, the first sub-anode electrode SAE1 may include a same material as the first lower transparent electrode LE1 or the first upper transparent electrode UE1. However, the material of the first sub-anode electrode SAE1 is not limited thereto.

The dam structure DAM may be disposed between two adjacent anode electrodes in the plan view. In an embodiment, for example, the dam structure DAM may be disposed between the first anode electrode AE1 and the second anode electrode AE2.

In such an embodiment, the dam structure DAM may be configured to overlap at least some of the edges of the first to third anode electrodes AE1, AE2, and AE3 illustrated in FIG. 6. In an embodiment, for example, the dam structure DAM may be configured to overlap the edge of the first anode electrode AE1 and surround the first anode electrode AE1 in the plan view. In another embodiment, for example, the dam structure DAM may be configured to overlap only a portion of the edge of the first anode electrode AE1.

In the area where the dam structure DAM is provided, the dam structure DAM may cover the side surface of the first anode electrode AE1. In an embodiment, for example, the dam structure DAM may directly cover the side surfaces of the first lower transparent electrode LE1, the first reflective electrode RE1, and the first upper electrode UE1.

In the area where the dam structure DAM is provided, the dam structure DAM may be in direct contact with the top surface of the first anode electrode AE1. In an embodiment, for example, the dam structure DAM may be in direct contact with a portion of the top surface of the first upper electrode UE1. In such an embodiment, the first sub-anode electrode SAE1 may be entirely provided on another portion of the top surface of the first upper electrode UE1 that is not in contact with (or exposed through) the dam structure DAM.

The dam structure DAM may serve to disconnect the first common layer CML1 between two adjacent anode electrodes. Accordingly, it is possible to prevent lateral leakage current from occurring between two adjacent anode electrodes through the first common layer CML1. To this end, the dam structure DAM may have an appropriate taper angle and an appropriate thickness. In an embodiment, for example, a taper angle ANG between the side surface of the dam structure DAM and the top surface of the first upper electrode UE1 in contact with the dam structure DAM may be in a range of about 45 degrees to about 60 degrees. In addition, the thickness in the third direction DR3 from the top surface of the first upper electrode UE1 to the top surface of the dam structure DAM may be about 300 angstroms or greater. However, the taper angle and the thickness of the dam structure DAM are not limited thereto.

The dam structure DAM may include an inorganic insulating material. In an embodiment, for example, the dam structure DAM may include at least one selected from silicon nitride, silicon oxide, and silicon oxynitride. However, the material of the dam structure DAM is not limited thereto.

The first common layer CML1 may be disposed between the first sub-anode electrode SAE1 and the emission stack layer ESTK. The first common layer CML1 may include various functional layers for improving the efficiency of light emitted from the emission stack layer ESTK. In an embodiment, for example, the first common layer CML1 may include a hole injection layer (HIL) and a hole transport layer (HTL), which are sequentially stacked in the third direction DR3. However, the types of functional layers included in the first common layer CML1 are not limited thereto.

The first common layer CML1 may be entirely disposed on the first sub-anode electrode SAE1 and the dam structure DAM. In an embodiment, the first common layer CML1 may be disconnected above the dam structure DAM, that is, a portion of the first common layer CML1 on a top surface of the dam structure DAM is disconnected from a portion of the first common layer CML1 on a side surface of the dam structure DAM. In an embodiment, for example, a first portion of the first common layer CML1 disposed on the first sub-anode electrode SAE1 and a second portion of the first common layer CML1 disposed on the top surface of the dam structure DAM may be spaced apart from each other.

The emission stack layer ESTK may be disposed on the first common layer CML1. The emission stack layer ESTK may be continuously disposed to cover components disposed below the emission stack layer ESTK. The emission stack layer ESTK may include a first emission layer EML1, a first light buffer layer EBUF1, a second emission layer EML2, a third emission layer EML3, and a second light buffer layer EBUF2, which are sequentially stacked one on another in the third direction DR3.

The first emission layer EML1 may be configured to emit first light in a first wavelength band. In an embodiment, for example, the first emission layer EML1 may be configured to emit light having a wavelength in a range of (or light in a wavelength range of) about 440 nm to about 480 nm. In this case, the first light may be blue light.

The first light buffer layer EBUF1 may be disposed between the first emission layer EML1 and the second emission layer EML2. The first light buffer layer EBUF1 may include various types of functional layers for improving the light efficiency of the emission stack layer ESTK. Depending on embodiments, the first light buffer layer EBUF1 may be omitted.

The second emission layer EML2 may be configured to emit second light in a second wavelength band. In an embodiment, for example, the second emission layer EML2 may be configured to emit light having a wavelength in a range of about 500 nm to about 540 nm. In this case, the second light may be green light.

The third emission layer EML3 may be configured to emit third light in a third wavelength band. In an embodiment, for example, the third emission layer EML3 may be configured to emit light having a wavelength in a range of about 610 nm to about 650 nm. In this case, the third light may be red light.

The second light buffer layer EBUF2 may be disposed on the third emission layer EML3. The second light buffer layer EBUF2 may include various types of functional layers for improving the light efficiency of the emission stack layer ESTK. Depending on embodiments, the second light buffer layer EBUF2 may be omitted.

The second common layer CML2 may be disposed between the emission stack layer ESTK and the cathode electrode CE. The second common layer CML2 may include various functional layers for improving the efficiency of light emitted from the emission stack layer ESTK. In an embodiment, for example, the second common layer CML2 may include an electron transport layer ETL and an electron injection layer EIL, which are sequentially stacked in the third direction DR3. However, the types of functional layers included in the second common layer CML2 are not limited thereto.

The first common layer CML1, the emission stack layer ESTK, and the second common layer CML2 may define the light emitting device (see LD of FIG. 2) of the first sub-pixel SP1. The first sub-pixel SP1 may be provided in a tandem structure including two or more emission layers configured to emit pieces of light having different wavelength bands.

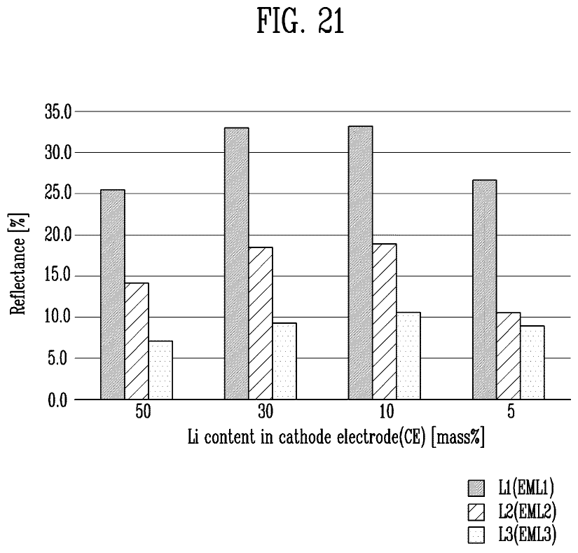

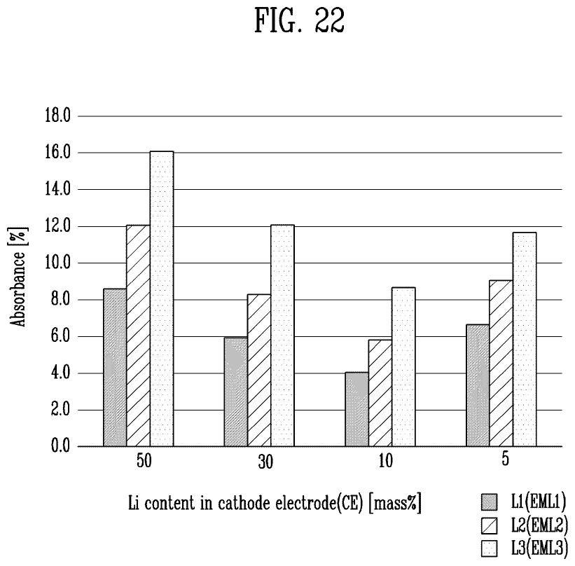

The cathode electrode CE may be disposed on the second common layer CML2. The cathode electrode CE may be configured to be substantially translucent. In an embodiment, the cathode electrode CE may include lithium (Li)-doped silver (Ag). The lithium (Li)-doped silver (Ag) may include greater than about 5 mass percent (mass %) and less than about 50 mass %, e.g., about 10 mass % or greater and about 30 mass % or less, of lithium (Li), based on the total mass of the lithium (Li)-doped silver (Ag). As the cathode electrode CE includes the above-described material, the cathode electrode CE may have an appropriate reflectance to induce a microcavity of light emitted from the emission stack layer ESTK. In addition, it is possible to effectively prevent light emitted from the emission stack layer ESTK from being excessively absorbed by the cathode electrode CE. This will be described later in greater detail with reference to FIGS. 21 and 22.

The capping layer CPL may be disposed on the cathode electrode CE. The capping layer CPL may serve to protect components below the capping layer CPL. In addition, the capping layer CPL may assist light generated in the emission stack layer ESTK to be efficiently emitted to the outside. The capping layer CPL may be provided as (or defined by) a single layer or multiple layers including an organic insulating material and/or an inorganic insulating material.

The encapsulation layer TFE may be disposed on the capping layer CPL. The encapsulation layer TFE may serve to protect components below the encapsulation layer TFE from impurities (e.g., moisture and/or gas). In an embodiment, for example, the encapsulation layer TFE may include a first inorganic encapsulation layer, an organic encapsulation layer, and a second inorganic encapsulation layer, which are stacked one on another in the third direction DR3.

The light functional layer LFL may be disposed on the encapsulation layer TFE. The light functional layer LFL may include a color filter layer including color filters and/or light conversion patterns having color conversion particles and/or scattering particles. In an embodiment, in the area where the first sub-pixel SP1 is provided, the light functional layer LFL may include a blue color filter that selectively transmits blue color light. However, the light functional layer LFL is not limited thereto.

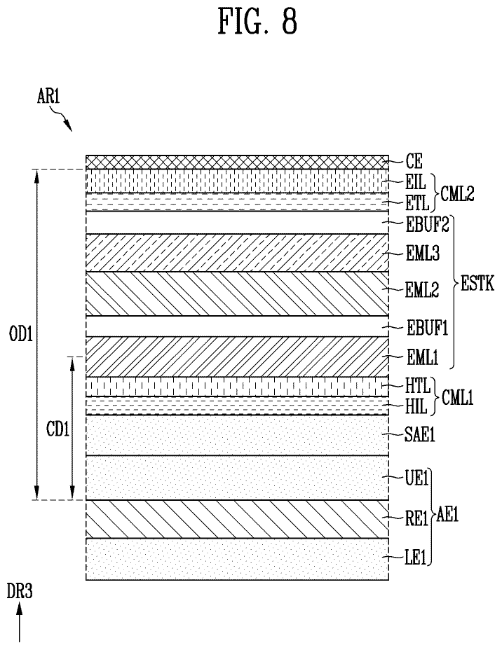

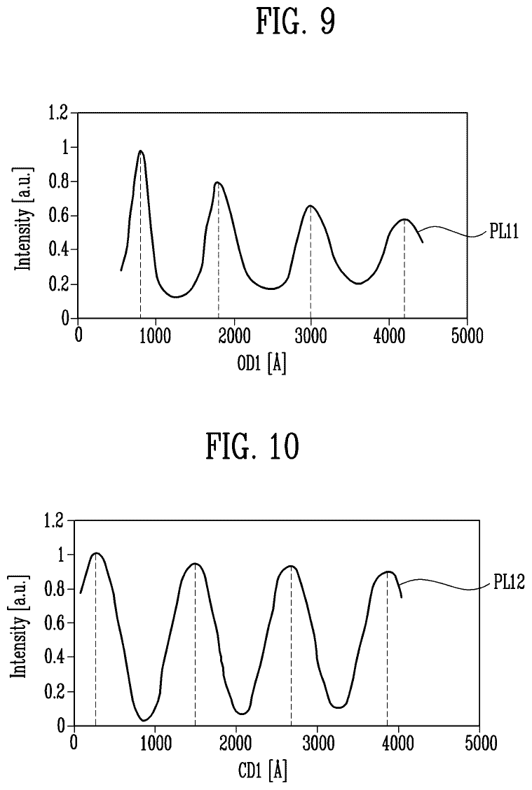

FIG. 8 is an enlarged cross-sectional view of a region AR1 of FIG. 7. FIGS. 9 and 10 are graphs showing the intensity of light emitted from the first emission layer as optical distances in the first sub-pixel change.

Referring to FIGS. 7 and 8, the first sub-pixel SP1 of the disclosure may have a first optical distance OD1. The first optical distance OD1 may be a distance at which light generated in the emission stack layer ESTK is reflected and resonated from reflective interfaces. The reflective interfaces may be defined on the top surface of the first reflective electrode RE1 and the bottom surface of the cathode electrode CE. The first optical distance OD1 may be defined by the physical distance from the interface between the first reflective electrode RE1 and the layer (e.g., the first upper electrode UE1) in contact with the first reflective electrode RE1 to the interface between the cathode electrode CE and the layer (e.g., the electron injection layer EIL) in contact with the cathode electrode CE and the refractive indices of the components UE1, SAE1, CML1, ESTK, and CML2 between the first reflective electrode RE1 and the cathode electrode CE. For example, the first optical distance OD1 may satisfy Equation 1-1 below.

$$OD 1 = ( {N}_{UE 1} \times {T}_{UE 1} ) + ( {N}_{SAE 1} \times {T}_{SAE 1} ) + ( {N}_{CML 1} \times {T}_{CML 1} ) + ( {N}_{E S T K} \times {T}_{E S T K )} + ( {N}_{CML 2} \times {T}_{CML 2} ) \qquad [ Equation 1 - 1 ]$$

In Equation 1-1 above, N_{UE1}, N_{SAE1}, N_{CML1}, N_{ESTK}, and N_{CML2} respectively denote refractive indices of the first upper electrode UE1, the first sub-anode electrode SAE1, the first common layer CML1, the emission stack layer ESTK, and the second common layer CML2.

In Equation 1-1 above, T_{UE1}, T_{SAE1}, T_{CML1}, T_{ESTK}, and T_{CML2} respectively denote thicknesses of the first upper electrode UE1, the first sub-anode electrode SAE1, the first common layer CML1, the emission stack layer ESTK, and the second common layer CML2 in the third direction DR3.

In an embodiment, the first sub-pixel SP1 may have a first resonance distance CD1 corresponding to the first emission layer EML1. The first resonance distance CD1 may be a distance at which light generated at the emission center of the first emission layer EML1 is reflected and resonated from the top surface of the first reflective electrode RE1, which is the reflection interface. The emission center of the first emission layer EML1 may correspond to the central portion where light generated in the first emission layer EML1 is emitted. In an embodiment, for example, the emission center of the first emission layer EML1 may be a point that is half the thickness of the first emission layer EML1. The first resonance distance CD1 may be defined by the physical distance from the emission center of the first emission layer EML1 to the top surface of the first reflective electrode RE1 and the refractive indices of the elements UE1, SAE1, CML1, and EML1 between the emission center of the first emission layer EML1 and the first reflective electrode RE1. For example, the first resonance distance CD1 may satisfy Equation 1-2 below.

$$CD 1 = ( {N}_{UE 1} \times {T}_{UE 1} ) + ( {N}_{SAE 1} \times {T}_{SAE 1} ) + ( {N}_{CML 1} \times {T}_{CML 1} ) + ( {N}_{EML 1} \times 0.5 {T}_{EML 1} ) \qquad [ Equation 1 - 2 ]$$

In Equation 1-2, N_{UE1}, N_{SAE1}, N_{CML1}, T_{UE1}, T_{SAE1}, and T_{CML1} are the same as those in Equation 1-1.

In Equation 1-2, N_{EML1} denote the refractive index of the first emission layer EML1, and T_{EML1} denotes the thickness of the first emission layer EML1 in the third direction DR3.

Referring to FIGS. 8 and 9, a first first graph (hereinafter, will be referred to as “1-1 graph”) PL11 is shown in FIG. 9. In the 1-1 graph PL11, the horizontal axis represents the first optical distance OD1, and the vertical axis represents the intensity of the first light of the first wavelength band generated in the first emission layer EML1. In FIG. 9, the 1-1 graph PL11 exemplarily shows a change in the intensity of blue light in an embodiment.

The light emitted from the first emission layer EML1 has a peak intensity at each certain first optical distance OD1. This peak intensity may correspond to the resonance state of light emitted from the first emission layer EML1 and tends to decrease as the first optical distance OD1 increases. When the length having the peak intensity is set as the first optical distance OD1, high light extraction efficiency of the light emitted from the first emission layer EML1 may be ensured.

In an embodiment of the disclosure, the first optical distance OD1 may be about 700 angstroms or greater and about 800 angstroms or less. This may be a length that is substantially the same as (or similar to) the length at which the first peak intensity appears in the 1-1 graph PL11. Accordingly, in an embodiment where the first optical distance OD1 satisfies the numerical range described above, high light extraction efficiency of light emitted from the first emission layer EML1 may be ensured.

Referring to FIGS. 8 and 10, a second first graph (hereinafter, will be referred to as “1-2 graph”) PL12 is shown in FIG. 10. In the 1-2 graph PL12, the horizontal axis represents the first resonance distance CD1, and the vertical axis represents the intensity of the first light of the first wavelength band generated in the first emission layer EML1. In FIG. 10, the 1-2 graph PL12 exemplarily shows a change in the intensity of blue light in an embodiment.

By controlling the first resonance distance CD1, there is substantially no difference in intensity, but a resonance distance with peak intensity may be designed. As described above, since the first optical distance OD1 is set to about 700 angstroms or greater and about 800 angstroms or less, the first resonance distance CD1 may be desired to set to be substantially less than the first optical distance OD1.

In an embodiment of the disclosure, the first resonance distance CD1 may be about 250 angstroms or greater and about 300 angstroms or less. This may be a length that is substantially the same as (or similar to) the length at which the first peak intensity appears in the 1-2 graph PL12. Accordingly, in an embodiment where the first resonance distance CD1 satisfies the numerical range described above, high light extraction efficiency of light emitted from the first emission layer EML1 may be ensured.

FIG. 11 is a cross-sectional view taken along line I2-I3 of FIG. 6. FIG. 11 is a cross-sectional view showing the second sub-pixel of FIG. 6.

Referring to FIGS. 6 and 11, in an embodiment, the pixel circuit layer PCL, the display element layer DPL, and the light functional layer LFL may be sequentially disposed on the substrate SUB.

The pixel circuit layer PCL may be substantially the same as that described above with reference to FIG. 7. In an embodiment, for example, the pixel circuit layer PCL may include various components constituting the sub-pixel circuit (see SPC of FIG. 2) of the second sub-pixel SP2.

The display element layer DPL may be disposed on the pixel circuit layer PCL. The display element layer DPL may include a second anode electrode AE2, a first resonance auxiliary structure RALa, a second sub-anode electrode SAE2, a dam structure DAM, a first common layer CML1, an emission stack layer ESTK, a second common layer CML2, a cathode electrode CE, a capping layer CPL, and an encapsulation layer TFE.

The second anode electrode AE2 may be disposed on the pixel circuit layer PCL. The second anode electrode AE2 may be electrically connected to at least one transistor among the transistors constituting the sub-pixel circuit SPC of the second sub-pixel SP2.

The second anode electrode AE2 may include a second lower transparent electrode LE2, a second reflective electrode RE2, and a second upper transparent electrode UE2, which are sequentially stacked in the third direction DR3. The second lower transparent electrode LE2, the second reflective electrode RE2, and the second upper transparent electrode UE2 may be configured to be substantially the same as (or similar to) the first lower transparent electrode LE1, the first reflective electrode RE1, and the first upper transparent electrode UE1, which have been described with reference to FIG. 7. Therefore, any repetitive detailed descriptions thereof will be omitted.

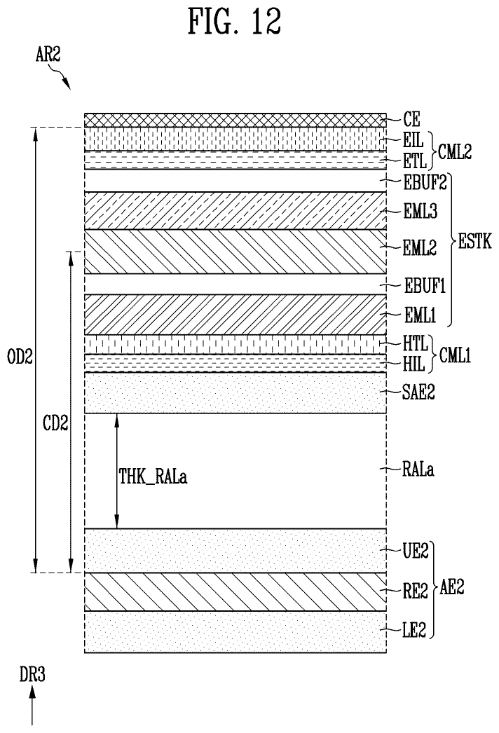

The first resonance auxiliary structure RALa may be disposed on the second anode electrode AE2. In an embodiment, for example, the bottom surface of the first resonance auxiliary structure RALa may be in direct contact with the top surface of the second upper transparent electrode UE2. The first resonance auxiliary structure RALa may have a first thickness in the third direction DR3. In such an embodiment, high light extraction efficiency of light emitted from the second emission layer EML2 may be ensured by the first resonance auxiliary structure RALa. This will be described later in greater detail with reference to FIGS. 12 to 14.

The second sub-anode electrode SAE2 may be disposed on the second anode electrode AE2 to cover the first resonance auxiliary structure RALa. The second sub-anode electrode SAE2 may be in electrical contact with the second anode electrode AE2. In an embodiment, for example, the second sub-anode electrode SAE2 may be in electrical contact with a non-overlapping surface of the top surface of the second upper electrode UE2 that does not overlap the dam structure DAM and the first resonance auxiliary structure RALa. In such an embodiment, the outer circumferential surface of the first resonance auxiliary structure RALa may be directly covered by the second sub-anode electrode SAE2 and the second upper transparent electrode UE2. The second sub-anode electrode SAE2 may be configured to be substantially transparent or translucent to satisfy certain light transmittance. In an embodiment, for example, the second sub-anode electrode SAE2 may include a same material as the first sub-anode electrode SAE1.

In an embodiment, the second sub-anode electrode SAE2 is disposed to cover the first resonance auxiliary structure RALa, such that a sufficient contact area between the second sub-anode electrode SAE2 and the first common layer CML1 may be ensured. Accordingly, the driving efficiency of the second sub-pixel SP2 may be improved. In a case, where the second sub-anode electrode SAE2 is omitted or when the first resonance auxiliary structure RALa is disposed on the second sub-anode electrode SAE2, the driving efficiency of the second sub-pixel SP2 may be lowered.

The dam structure DAM may be substantially the same (or similar) as that described above with reference to FIG. 7. In an embodiment, for example, the dam structure DAM may be configured to overlap the edge of the second anode electrode AE2 and surround the second anode electrode AE2. In another embodiment, for example, the dam structure DAM may be configured to overlap a portion of the edge of the second anode electrode AE2. In the area where the dam structure DAM is provided, the dam structure DAM may cover the side surface of the second anode electrode AE2. In the area where the dam structure DAM is provided, the dam structure DAM may be in direct contact with the top surface of the second anode electrode AE2.

The first common layer CML1 may be substantially the same (or similar) as that described above with reference to FIG. 7. The first common layer CML1 may be disposed between the second sub-anode electrode SAE2 and the emission stack layer ESTK. The first common layer CML1 may be continuously disposed throughout the areas where the first and second sub-pixels SP1 and SP2 are provided, but may be disconnected above the dam structure DAM.

The emission stack layer ESTK may be substantially the same (or similar) as that described above with reference to FIG. 7. The emission stack layer ESTK may be continuously disposed throughout the areas where the first and second sub-pixels SP1 and SP2 are provided.

The second common layer CML2 may be substantially the same manner as that described above with reference to FIG. 7. The second common layer CML2 may be continuously disposed throughout the areas where the first and second sub-pixels SP1 and SP2 are provided.

The first common layer CML1, the emission stack layer ESTK, and the second common layer CML2 may define the light emitting device (see LD of FIG. 2) of the second sub-pixel SP2. The second sub-pixel SP2 may be provided in a tandem structure including two or more emission layers configured to emit pieces of light having different wavelength bands.

The cathode electrode CE may be substantially the same (as that described above with reference to FIG. 7. The cathode electrode CE may be continuously disposed throughout the areas where the first and second sub-pixels SP1 and SP2 are provided.

The capping layer CPL and the encapsulation layer TFE may be substantially the same as those described above with reference to FIG. 7. The capping layer CPL and the encapsulation layer TFE may be continuously disposed throughout the areas where the first and second sub-pixels SP1 and SP2 are provided.

The light functional layer LFL may be disposed on the encapsulation layer TFE. The light functional layer LFL may include a color filter layer including color filters and/or light conversion patterns having color conversion particles and/or scattering particles. In an embodiment, in the area where the second sub-pixel SP2 is provided, the light functional layer LFL may include a green color filter that selectively transmits green color light. However, the light functional layer LFL is not limited thereto.

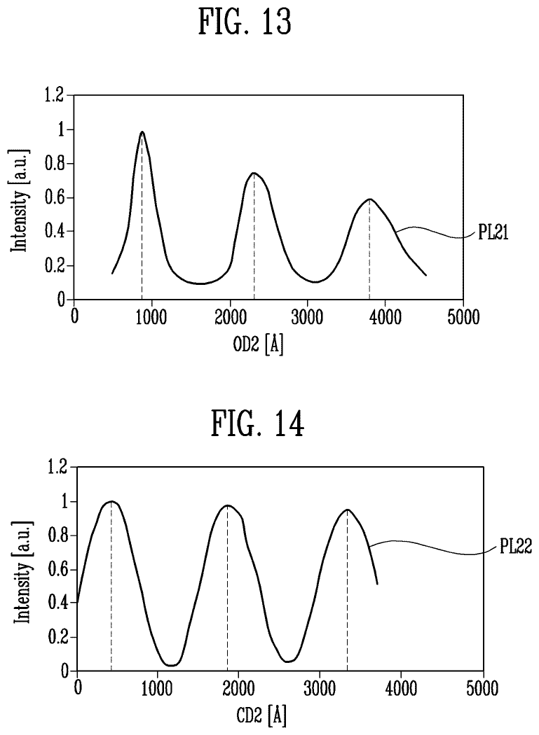

FIG. 12 is an enlarged cross-sectional view of a region AR2 of FIG. 11. FIGS. 13 and 14 are graphs showing the intensity of light emitted from the second emission layer as optical distances in the second sub-pixel change.

Referring to FIGS. 11 and 12, in an embodiment, the second sub-pixel SP2 may have a second optical distance OD2. The second optical distance OD2 may be a distance at which light generated in the emission stack layer ESTK is reflected and resonated from reflective interfaces. The reflective interfaces may be defined on the top surface of the second reflective electrode RE2 and the bottom surface of the cathode electrode CE. The second optical distance OD2 may be defined by the physical distance from the top surface of the second reflective electrode RE2 to the bottom surface of the cathode electrode CE and the refractive indices of the components UE2, RALa, SAE2, CML1, ESTK, and CML2 between the second reflective electrode RE2 and the cathode electrode CE. For example, the second optical distance OD2 may satisfy Equation 2-1 below.

$$OD 2 = ( {N}_{UE 2} \times {T}_{UE 2} ) + ( {N}_{R A L a} \times {T}_{R A L a} ) + ( {N}_{S A E 2} \times {T}_{S A E 2} ) + ( {N}_{CML 1} \times {T}_{CML 1} ) + ( {N}_{E S T K} \times {T}_{E S T K} ) + ( {N}_{CML 2} \times {T}_{CML 2} ) \qquad [ Equation 2 - 1 ]$$

In Equation 2-1 above, N_{UE2}, N_{RALa}, N_{SAE2}, N_{CML1}, N_{ESTK}, and N_{CML2} respectively denote the refractive indices of the second upper electrode UE2, the first resonance auxiliary structure RALa, the second sub-anode electrode SAE2, the first common layer CML1, the emission stack layer ESTK, and the second common layer CML2.

In Equation 2-1 above, T_{UE2}, T_{RALa}, T_{SAE2}, T_{CML1}, T_{ESTK}, and T_{CML2} respectively denote the thicknesses of the second upper electrode UE2, the first resonance auxiliary structure RALa, the second sub-anode electrode SAE2, the first common layer CML1, the emission stack layer ESTK, and the second common layer CML2 in the third direction DR3.

Here, T_{RALa} may be a first thickness THK_RALa which will be described later.

In an embodiment, the second sub-pixel SP2 may have a second resonance distance CD2 corresponding to the second emission layer EML2. The second resonance distance CD2 may be a distance at which light generated at the emission center of the second emission layer EML2 is reflected and resonated from the top surface of the second reflective electrode RE2, which is the reflection interface. The emission center of the second emission layer EML2 may correspond to the central portion where light generated in the second emission layer EML2 is emitted. For example, the emission center of the second emission layer EML2 may be a point that is half the thickness of the second emission layer EML2. The second resonance distance CD2 may be defined by the physical distance from the emission center of the second emission layer EML2 to the top surface of the second reflective electrode RE2 and the refractive indices of the elements UE2, RALa, SAE2, CML1, EML1, EBUF1, and EML2 between the emission center of the second emission layer EML2 and the second reflective electrode RE2. For example, the second resonance distance CD2 may satisfy Equation 2-2 below.

$$CD 2 = ( {N}_{UE 2} \times {T}_{UE 2} ) + ( {N}_{R A L a} \times {T}_{R A L a} ) + ( {N}_{SAE 2} \times {T}_{SAE 2} ) + ( {N}_{CML 1} \times {T}_{CML 1} ) + ( {N}_{EML 1} \times {T}_{EML 1} ) + ( {N}_{EBUF 1} \times {T}_{EBUF 1} ) + ( {N}_{EML 2} \times 0.5 {T}_{EML 2} ) \qquad [ Equation 2 - 2 ]$$

In Equation 2-2 above, N_{UE2}, N_{RALa}, N_{SAE2}, N_{CML1}, T_{UE2}, T_{RALa}, T_{SAE2}, and T_{CML1} are the same as those in Equation 2-1 above.

In Equation 2-2, N_{EML1}, N_{EBUF1}, and N_{EML2} respectively denote the refractive indices of the first emission layer EML1, the first optical buffer layer EBUF1, and the second emission layer EML2.

In Equation 2-2, T_{EML1}, T_{EBUF1}, and T_{EML2} respectively denote the thicknesses of the first emission layer EML1, the first light buffer layer EBUF1, and the second emission layer EML2 in the third direction DR3.

Referring to FIGS. 12 and 13, a first second graph (hereinafter will be referred to as “2-1 graph”) PL21 is shown in FIG. 13. In the 2-1 graph PL21, the horizontal axis represents the second optical distance OD2, and the vertical axis represents the intensity of the second light of the second wavelength band generated in the second emission layer EML2. In FIG. 13, the 2-1 graph PL21 exemplarily shows a change in the intensity of green light in an embodiment.

The light emitted from the second emission layer EML2 has a peak intensity at each certain second optical distance OD2. This peak intensity may correspond to the resonance state of light emitted from the second emission layer EML2 and tends to decrease as the second optical distance OD2 increases. When the length having the peak intensity is set as the second optical distance OD2, excellent light extraction efficiency of the light emitted from the second emission layer EML2 may be ensured.

The length at which the first peak intensity appears in the 2-1 graph PL21 may be greater than the length at which the first peak intensity appears in the 1-1 graph (see PL11 of FIG. 9). In an embodiment of the disclosure, the second optical distance OD2 may be set to be substantially the same as (or similar to) the length at which the first peak intensity appears in the 2-1 graph PL21. In such an embodiment, the first resonance auxiliary structure RALa may be disposed between the second sub-anode electrode SAE2 and the second anode electrode AE2. The first resonance auxiliary structure RALa may have a first thickness THK_RALa in the third direction DR3. Accordingly, the first resonance auxiliary structure RALa may compensate the second optical distance OD2 by the first thickness THK_RALa in the area where the second sub-pixel SP2 is provided. Accordingly, in an embodiment, the second optical distance OD2 may be set to be substantially the same as (or similar to) the length at which the first peak intensity appears in the 2-1 graph PL21.

Referring to FIGS. 12 and 14, a second graph (hereinafter, will be referred to as “2-2 graph”) PL22 is shown in FIG. 14. In the 2-2 graph PL22, the horizontal axis represents the second resonance distance CD2, and the vertical axis represents the intensity of the second light of the second wavelength band generated in the second emission layer EML2. In FIG. 14, the 2-2 graph PL22 exemplarily shows a change in the intensity of green light in an embodiment.

By controlling the second resonance distance CD2, there is substantially no difference in intensity, but a resonance distance with peak intensity may be designed. The length at which the first peak intensity appears in the 2-2 graph PL22 may be greater than the length at which the first peak intensity appears in the 1-2 graph (see PL12 of FIG. 10). In an embodiment of the disclosure, the second resonance distance CD2 may be set to be substantially the same as (or similar to) the length at which the first peak intensity appears in the 2-2 graph PL22. To this end, the first resonance auxiliary structure RALa may be disposed between the second sub-anode electrode SAE2 and the second anode electrode AE2. The first resonance auxiliary structure RALa may have a first thickness THK_RALa in the third direction DR3. Accordingly, in an embodiment, the first resonance auxiliary structure RALa may compensate the second resonance distance CD2 by the first thickness THK_RALa in the area where the second sub-pixel SP2 is provided. Accordingly, the second resonance distance CD2 may be set to be substantially the same as (or similar to) the length at which the first peak intensity appears in the 2-2 graph PL22.

Referring to FIGS. 12 to 14, as described above, the first resonance auxiliary structure RALa may compensate for each of the second optical distance OD2 and the second resonance distance CD2 by the first thickness THK_RALa. Accordingly, in an embodiment, the second optical distance OD2 may be set to be substantially the same as (or similar to) the length at which the first peak intensity appears in the 2-1 graph PL21. In addition, the second resonance distance CD2 may be set to be substantially the same as (or similar to) the length at which the first peak intensity appears in the 2-2 graph PL22. Therefore, in an embodiment, high light extraction efficiency of light emitted from the second emission layer EML2 may be ensured.

In an embodiment, the first thickness THK_RALa may be about 150 angstroms or greater and about 350 angstroms or less. In such an embodiment, the optimal second optical distance OD2 and the optimal second resonance distance CD2 may be set.

FIG. 15 is a cross-sectional view taken along line I3-I4 of FIG. 6. FIG. 15 is a cross-sectional view showing the third sub-pixel of FIG. 6.

Referring to FIGS. 6 and 15, in an embodiment, the pixel circuit layer PCL, the display element layer DPL, and the light functional layer LFL may be sequentially disposed on the substrate SUB.

The pixel circuit layer PCL may be substantially the same as that described above with reference to FIG. 7. In an embodiment, for example, the pixel circuit layer PCL may include various components constituting the sub-pixel circuit (see SPC of FIG. 3) of the second sub-pixel SP3.

The display element layer DPL may be disposed on the pixel circuit layer PCL. The display element layer DPL may include a third anode electrode AE3, a second resonance auxiliary structure RALb, a third sub-anode electrode SAE3, a dam structure DAM, a first common layer CML1, an emission stack layer ESTK, a second common layer CML2, a cathode electrode CE, a capping layer CPL, and an encapsulation layer TFE.

The third anode electrode AE3 may be disposed on the pixel circuit layer PCL. The third anode electrode AE3 may be electrically connected to at least one transistor among the transistors constituting the sub-pixel circuit SPC of the third sub-pixel SP3.

The third anode electrode AE3 may include a third lower transparent electrode LE3, a third reflective electrode RE3, and a third upper transparent electrode UE3, which are sequentially stacked in the third direction DR3. The third lower transparent electrode LE3, the third reflective electrode RE3, and the third upper transparent electrode UE3 may be substantially the same as the first lower transparent electrode LE1, the first reflective electrode RE1, and the first upper transparent electrode UE1, which are described above with reference to FIG. 7. Therefore, any repetitive detailed descriptions thereof will be omitted.

The second resonance auxiliary structure RALb may be disposed on the third anode electrode AE3. In an embodiment, for example, the bottom surface of the second resonance auxiliary structure RALb may be in direct contact with the top surface of the third upper transparent electrode UE3. The second resonance auxiliary structure RALb may have a second thickness in the third direction DR3. In such an embodiment, high light extraction efficiency of light emitted from the third emission layer EML3 may be ensured by the second resonance auxiliary structure RALb. This will be described later in greater detail with reference to FIGS. 16 to 18.

The third sub-anode electrode SAE3 may be disposed on the third anode electrode AE3 to cover the second resonance auxiliary structure RALb. The third sub-anode electrode SAE3 may be in electrical contact with the third anode electrode AE3. In an embodiment, for example, the third sub-anode electrode SAE3 may be in electrical contact with a non-overlapping surface of the top surface of the third upper electrode UE3 that does not overlap the dam structure DAM and the second resonance auxiliary structure RALb. In such an embodiment, the outer circumferential surface of the second resonance auxiliary structure RALb may be directly covered by the third sub-anode electrode SAE3 and the third upper transparent electrode UE3. The third sub-anode electrode SAE3 may be configured to be substantially transparent or translucent to satisfy certain light transmittance. In an embodiment, for example, the third sub-anode electrode SAE3 may include a same material as the first sub-anode electrode SAE1.

In an embodiment, where the third sub-anode electrode SAE3 is disposed to cover the second resonance auxiliary structure RALb, a sufficient contact area between the third sub-anode electrode SAE3 and the first common layer CML1 may be ensured. Accordingly, the driving efficiency of the third sub-pixel SP3 may be improved.

The dam structure DAM may be substantially the same as that described above with reference to FIG. 7. In an embodiment, for example, the dam structure DAM may be configured to overlap the edge of the third anode electrode AE3 and surround the third anode electrode AE3. In another embodiment, for example, the dam structure DAM may be configured to overlap a portion of the edge of the third anode electrode AE3. In the area where the dam structure DAM is provided, the dam structure DAM may cover the side surface of the third anode electrode AE3. In the area where the dam structure DAM is provided, the dam structure DAM may be in direct contact with the top surface of the third anode electrode AE.

The first common layer CML1 may be substantially the same as that described above with reference to FIG. 7. The first common layer CML1 may be disposed between the third sub-anode electrode SAE3 and the emission stack layer ESTK. The first common layer CML1 may be continuously disposed throughout the areas where the first to third sub-pixels SP1, SP2, and SP3 are provided, but may be disconnected above the dam structure DAM.

The emission stack layer ESTK may be substantially the same as that described above with reference to FIG. 7. The emission stack layer ESTK may be continuously disposed throughout the areas where the first to third sub-pixels SP1, SP2, and SP3 are provided.

The second common layer CML2 may be substantially the same as that described above with reference to FIG. 7. The second common layer CML2 may be continuously disposed throughout the areas where the first to third sub-pixels SP1, SP2, and SP3 are provided.

The first common layer CML1, the emission stack layer ESTK, and the second common layer CML2 may define the light emitting device (see LD of FIG. 2) of the third sub-pixel SP3. The third sub-pixel SP3 may be provided in a tandem structure including two or more emission layers configured to emit pieces of light having different wavelength bands.

The cathode electrode CE may be substantially the same as that described above with reference to FIG. 7. The cathode electrode CE may be continuously disposed throughout the areas where the first to third sub-pixels SP1, SP2, and SP3 are provided.

The capping layer CPL and the encapsulation layer TFE may be substantially the same as those described above with reference to FIG. 7. The capping layer CPL and the encapsulation layer TFE may be continuously disposed throughout the areas where the first to third sub-pixels SP1, SP2, and SP3 are provided.

The light functional layer LFL may be disposed on the encapsulation layer TFE. The light functional layer LFL may include a color filter layer including color filters and/or light conversion patterns having color conversion particles and/or scattering particles. In an embodiment, in the area where the third sub-pixel SP3 is provided, the light functional layer LFL may include a red color filter that selectively transmits red color light. However, the light functional layer LFL is not limited thereto.

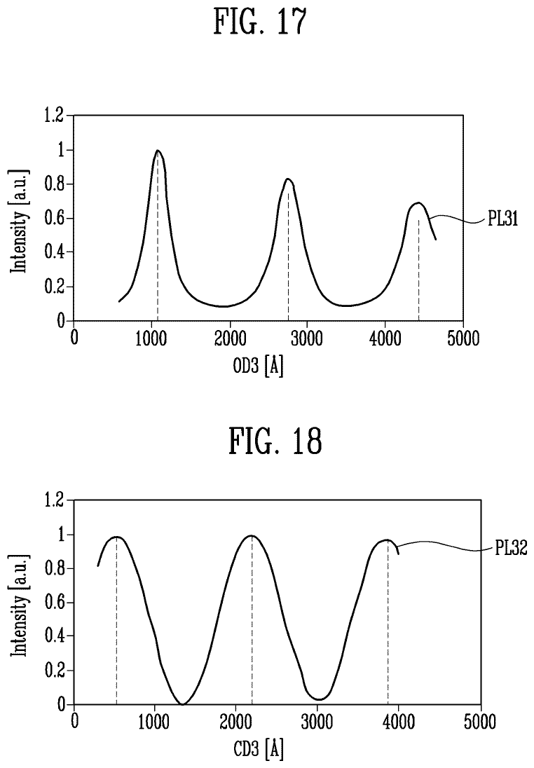

FIG. 16 is an enlarged cross-sectional view of a region AR3 of FIG. 15. FIGS. 17 and 18 are graphs showing the intensity of light emitted from the third emission layer as optical distances in a third sub-pixel change.

Referring to FIGS. 15 and 16, the third sub-pixel SP3 of the disclosure may have a third optical distance OD3. The third optical distance OD3 may be a distance at which light generated in the emission stack layer ESTK is reflected and resonated from reflective interfaces. The reflective interfaces may be defined on the top surface of the second reflective electrode RE2 and the bottom surface of the cathode electrode CE. The third optical distance OD3 may be defined by the physical distance from the top surface of the third reflective electrode RE3 to the bottom surface of the cathode electrode CE and the refractive indices of the components UE3, RALb, SAE3, CML1, ESTK, and CML2 between the third reflective electrode RE3 and the cathode electrode CE. For example, the third optical distance OD3 may satisfy Equation 3-1 below.

$$OD 3 = ( {N}_{UE 3} \times {T}_{UE 3} ) + ( {N}_{R A L b} \times {T}_{RALb} ) + ( {N}_{SAE 3} \times {T}_{SAE 3} ) + ( {N}_{CML 1} \times {T}_{CML 1} ) + ( {N}_{E S T K} \times {T}_{E S T K} ) + ( {N}_{CML 2} \times {T}_{CML 2} ) \qquad [ Equation 3 - 1 ]$$

In Equation 3-1 above, N_{UE3}, N_{RALb}, N_{SAE3}, N_{CML1}, N_{ESTK}, and N_{CML2} respectively denote the refractive indices of the third upper electrode UE3, the second resonance auxiliary structure RALb, the third sub-anode electrode SAE3, the first common layer CML1, the emission stack layer ESTK, and the second common layer CML2.

In Equation 3-1, T_{UE3}, T_{RALb}, T_{SAE3}, T_{CML1}, T_{ESTK}, and T_{CML2} respectively denote the thicknesses of the third upper electrode UE3, the second resonance auxiliary structure RALb, the third sub-anode electrode SAE3, the first common layer CML1, the emission stack layer ESTK, and the second common layer CML2 in the third direction DR3.

Here, T_{RALb} may be a second thickness THK_RALb, which will be described later.

In an embodiment, the third sub-pixel SP3 may have a third resonance distance CD3 corresponding to the third emission layer EML3. The third resonance distance CD3 may be a distance at which light generated at the emission center of the third emission layer EML3 is reflected and resonated from the top surface of the second reflective electrode RE3, which is the reflection interface. The emission center of the third emission layer EML3 may correspond to the central portion where light generated in the third emission layer EML3 is emitted. In an embodiment, for example, the emission center of the third emission layer EML3 may be a point that is half the thickness of the third emission layer EML3. The third resonance distance CD3 may be defined by the physical distance from the emission center of the third emission layer EML3 to the top surface of the third reflective electrode RE3 and the refractive indices of the elements UE3, RALb, SAE3, CML1, EML1, EBUF1, EML2, and EML3 between the emission center of the third emission layer EML3 and the third reflective electrode RE3. For example, the third resonance distance CD3 may satisfy Equation 3-2 below.

$$CD 3 = ( {N}_{UE 3} \times {T}_{UE 3} ) + ( {N}_{R A L b} \times {T}_{RALb} ) + ( {N}_{S A E 3} \times {T}_{SAE 3} ) + ( {N}_{CML 1} \times {T}_{CML 1} ) + ( {N}_{EML 1} \times {T}_{EML 1} ) + ( {N}_{EBUF 1} \times {T}_{EBUF 1} ) + ( {N}_{E M L 2} \times {T}_{EML 2} ) + ( {N}_{EML 3} \times 0.5 {T}_{EML 3} ) \qquad [ Equation 3 - 2 ]$$

In Equation 3-2, N_{UE3}, N_{RALb}, N_{SAE3}, N_{CML1}, T_{UE2}, T_{RALa}, T_{SAE2}, and T_{CML1} are the same as those in Equation 3-1 above.

In Equation 3-2, N_{EML1}, N_{EBUF1}, N_{EML2}, and N_{EML3} respectively denote the refractive indices of the first emission layer EML1, the first light buffer layer EBUF1, the second emission layer EML2, and the third emission layer EML3.

In Formula 3-2, T_{EML1}, T_{EBUF1}, T_{EML2}, and T_{EML3} respectively denote the thicknesses of the first emission layer EML1, the first light buffer layer EBUF1, the second emission layer EML2, and the third emission layer EML3 in the third direction DR3.

Referring to FIGS. 16 and 17, a first third graph (hereinafter, will be referred to as “3-1 graph”) PL31 is shown in FIG. 17. In the 3-1 graph PL31, the horizontal axis represents the third optical distance OD3, and the vertical axis represents the intensity of the third light of the third wavelength band generated in the third emission layer EML3. In FIG. 17, the 3-1 graph PL31 exemplarily shows a change in the intensity of red light in an embodiment.

The light emitted from the third emission layer EML3 has a peak intensity at each certain third optical distance OD3. This peak intensity may correspond to the resonance state of light emitted from the third emission layer EML3 and tends to decrease as the third optical distance OD3 increases. In an embodiment where the length having the peak intensity is set as the third optical distance OD3, high light extraction efficiency of the light emitted from the third emission layer EML3 may be ensured.

The length at which the first peak intensity appears in the 3-1 graph PL31 may be greater than the length at which the first peak intensity appears in the 1-1 graph (see PL11 of FIG. 9). The length at which the first peak intensity appears in the 3-1 graph PL31 may be greater than the length at which the first peak intensity appears in the 1-1 graph (see PL21 of FIG. 13). In the disclosure, the third optical distance OD3 may be set to be substantially the same as (or similar to) the length at which the first peak intensity appears in the 3-1 graph PL31. To this end, the second resonance auxiliary structure RALb may be disposed between the third sub-anode electrode SAE3 and the third anode electrode AE3. The second resonance auxiliary structure RALb may have a second thickness THK_RALb in the third direction DR3. The second thickness THK_RALb may be greater than the first thickness (see THK_RALa of FIG. 12). Accordingly, in an embodiment, the second resonance auxiliary structure RALb may compensate the third optical distance OD3 by the second thickness THK_RALb in the area where the third sub-pixel SP3 is provided. Accordingly, the third optical distance OD3 may be set to be substantially the same as (or similar to) the length at which the first peak intensity appears in the 3-1 graph PL31.

Referring to FIGS. 16 and 18, a second third graph (hereinafter, will be referred to as “3-2 graph”) PL32 is shown in FIG. 18. In the 3-2 graph PL32, the horizontal axis represents the third resonance distance CD3, and the vertical axis represents the intensity of the third light of the third wavelength band generated in the third emission layer EML3. In FIG. 18, the 3-2 graph PL32 exemplarily shows a change in the intensity of red light in an embodiment.

By controlling the third resonance distance CD3, there is substantially no difference in intensity, but a resonance distance with peak intensity may be designed. The length at which the first peak intensity appears in the 3-2 graph PL32 may be greater than the length at which the first peak intensity appears in the 1-2 graph (see PL12 of FIG. 10). The length at which the first peak intensity appears in the 3-2 graph PL32 may be greater than the length at which the first peak intensity appears in the 2-2 graph (see PL22 of FIG. 14). In an embodiment of the disclosure, the second resonance distance CD3 may be set to be substantially the same as (or similar to) the length at which the first peak intensity appears in the 3-3 graph PL32. In such an embodiment, the second resonance auxiliary structure RALb may be disposed between the third sub-anode electrode SAE3 and the third anode electrode AE3. The second resonance auxiliary structure RALb may have a second thickness THK_RALb in the third direction DR3. The second thickness THK_RALb may be greater than the first thickness (see THK_RALa of FIG. 12). Accordingly, the second resonance auxiliary structure RALb may compensate the third resonance distance CD3 by the second thickness THK_RALb in the area where the third sub-pixel SP3 is provided. Accordingly, the third resonance distance CD3 may be set to be substantially the same as (or similar to) the length at which the first peak intensity appears in the 3-2 graph PL32.

Referring to FIGS. 16 to 18, as described above, the second resonance auxiliary structure RALb may compensate for each of the third optical distance OD3 and the third resonance distance CD3 by the second thickness THK_RALb. Accordingly, the third optical distance OD3 may be set to be substantially the same as (or similar to) the length at which the first peak intensity appears in the 3-1 graph PL31. In addition, the third resonance distance CD3 may be set to be substantially the same as (or similar to) the length at which the first peak intensity appears in the 3-2 graph PL32. Therefore, high light extraction efficiency of light emitted from the third emission layer EML3 may be ensured.

In an embodiment, the second thickness THK_RALb may be about 400 angstroms or greater and about 600 angstroms or less. In such an embodiment, the optimal third optical distance OD3 and the optimal third resonance distance CD3 may be set.

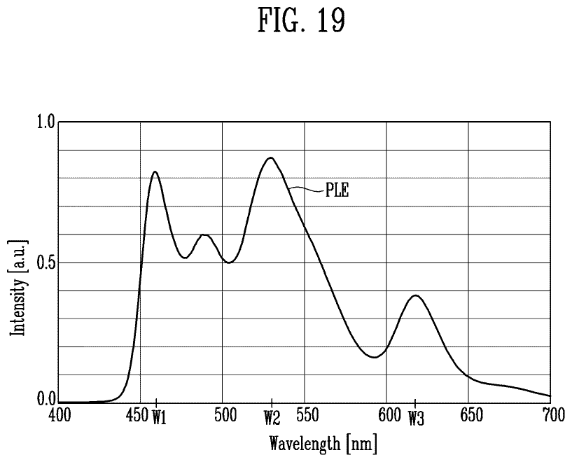

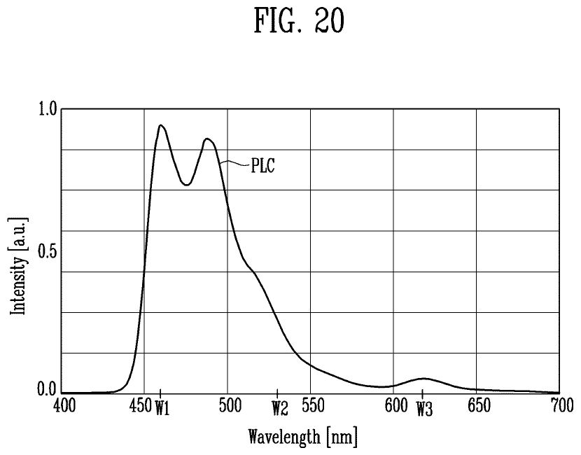

FIG. 19 is a graph showing the intensity of light emitted from a pixel including the first and second resonance auxiliary structures with respect to each wavelength. FIG. 20 is a graph showing the intensity of light emitted from a pixel not including first and second resonance auxiliary structures with respect to each wavelength.

Referring to FIG. 19, the intensity of light emitted from the pixel (see PXL of FIGS. 6 to 18) including the first and second resonance auxiliary structures RALa and RALb with respect to each wavelength is shown in a graph PLE. Referring to the graph PLE of FIG. 19, it may be confirmed that the intensity of light (e.g., blue light) having a first wavelength W1 is substantially the same as (or similar to) the intensity of light (e.g., green light) having a second wavelength (W2). In addition, it may be confirmed that the intensity of light (e.g., red light) having a third wavelength W3 is not excessively low.

Referring to FIG. 20, the intensity of light emitted from the pixel not including the first and second resonance auxiliary structures RALa and RALb with respect to each wavelength is shown in a graph PLC. Referring to the graph PLC of FIG. 20, it may be confirmed that, compared to the intensity of light having the first wavelength W1, the intensity of light having the second wavelength W2 and the intensity of light having the third wavelength W3 are very low. Accordingly, it may be confirmed that, when the first and second resonance auxiliary structures RALa and RALb are omitted, the light efficiency of the light having the second wavelength W2 and the light having the third wavelength W3 emitted from the pixel PXL are deteriorated.

FIG. 21 is a graph showing light reflectance versus a lithium content in a cathode electrode. FIG. 22 is a graph showing light absorbance versus a lithium content in a cathode electrode.

Referring to FIGS. 21 and 22, in an embodiment, the cathode electrode CE may include lithium (Li)-doped silver (Ag). The lithium (Li)-doped silver (Ag) may include greater than about 5 mass % and less than about 50 mass %, e.g., about 10 mass % or greater and about 30 mass % or less, of lithium (Li), based on the total mass of the lithium (Li)-doped silver (Ag). Additionally, the cathode electrode CE may be provided with a thickness of about 10 angstroms or greater and about 20 angstroms or less.

When the lithium (Li) content in the lithium (Li)-doped silver (Ag) satisfies the numerical range described above, as illustrated in FIG. 21, the cathode electrode CE may have a reflectance of a certain level or higher with respect to the first to third lights L1, L2, and L3 respectively emitted from the first to third emission layers EML1, EML2, and EML3. Accordingly, the first to third lights L1, L2, and L3 may effectively resonate between the cathode electrode CE and the first to third reflective electrodes RE1, RE2, and RE3. Here, the first light L1 may be blue light, the second light L2 may be green light, and the third light L3 may be red light.

In addition, when the lithium (Li) content in the lithium (Li)-doped silver (Ag) satisfies the numerical range described above, as illustrated in FIG. 22, the cathode electrode CE may have a relatively low light absorbance with respect to the first to third lights L1, L2, and L3 respectively emitted from the first to third emission layers EML1, EML2, and EML3. Accordingly, it is possible to effectively prevent the first to third lights L1, L2, and L3 from being absorbed and lost by the cathode electrode CE.

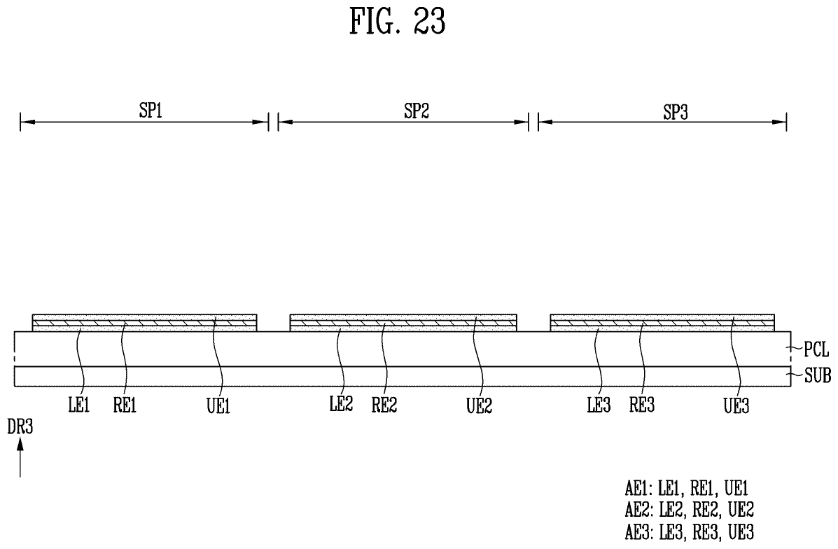

FIGS. 23 to 28 are cross-sectional views showing an embodiment of a method of manufacturing the pixel of FIG. 6.

Referring to FIG. 23, in an embodiment of a method of manufacturing the pixel, after forming a pixel circuit layer PCL on a substrate SUB, first to third anode electrodes AE1, AE2, and AE3 may be formed on the pixel circuit layer PCL.

In this operation, first to third lower transparent electrodes LE1, LE2, and LE3 may be formed through substantially the same forming process as each other, first to third reflective electrodes RE1, RE2, and RE3 may be formed through substantially the same forming process as each other, and first to third upper transparent electrodes UE1, UE2, and UE3 may be formed through substantially the same forming process as each other.

In an embodiment, for example, a first transparent electrode layer formed of a material constituting the first to third lower transparent electrodes LE1, LE2, and LE3, a reflective electrode layer formed of a material constituting the first to third reflective electrodes RE1, RE2, and RE3, and a second transparent electrode layer formed of a material constituting the first to third transparent upper electrodes UE1, UE2, and UE3 are sequentially formed on the pixel circuit layer PCL, and then, the first transparent electrode layer, the reflective electrode layer, and the second transparent electrode layer may be patterned.

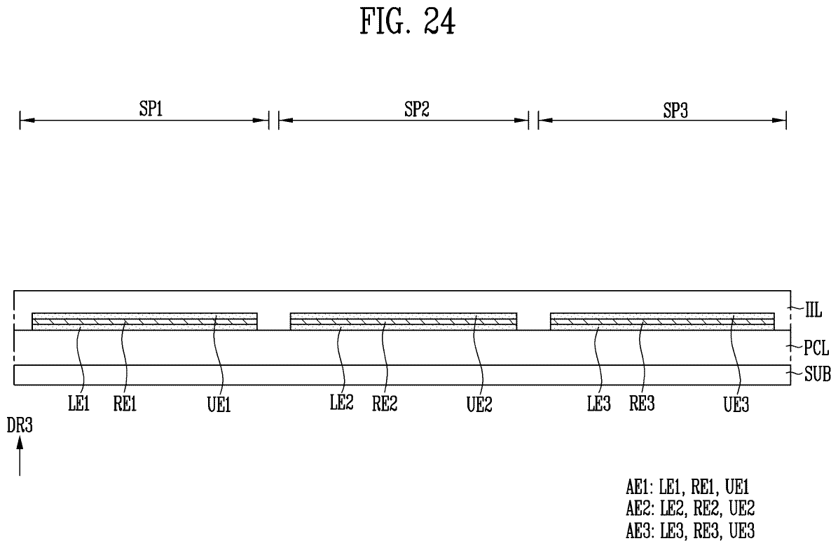

Referring to FIG. 24, an inorganic insulating layer IIL may be formed on the pixel circuit layer PCL. The inorganic insulating layer IIL may cover the first to third anode electrodes AE1, AE2, and AE3.

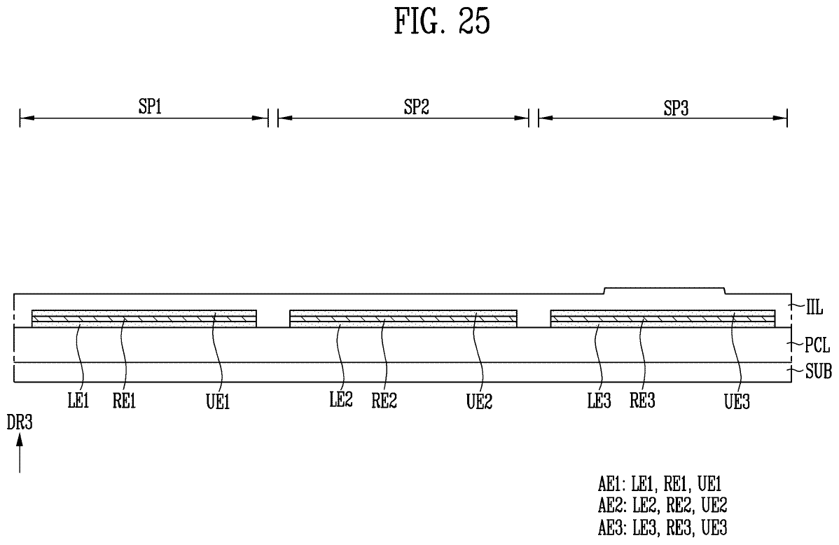

Referring to FIG. 25, the inorganic insulating layer IIL may be partially etched. In an embodiment, the inorganic insulating layer IIL may not be substantially etched in an area that overlaps a portion of the area where the third sub-pixel SP3 is provided. In such an embodiment, the inorganic insulating layer IIL may be etched in areas other than the above area overlapping the portion of the area where the third sub-pixel SP3 is provided to have a relatively low thickness.

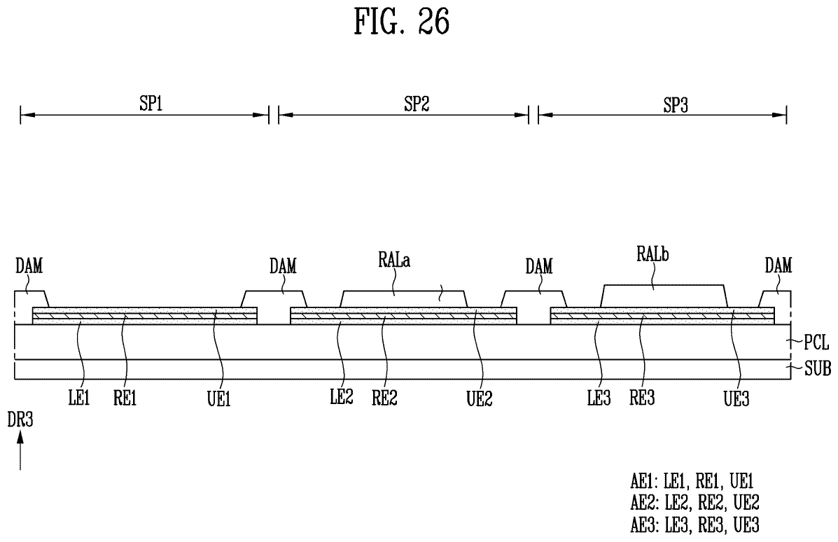

Referring to FIG. 26, the inorganic insulating layer IIL may be partially etched to form a dam structure DAM, a first resonance auxiliary structure RALa, and a second resonance auxiliary structure RALb. As such, the dam structure DAM, the first resonance auxiliary structure RALa, and the second resonance auxiliary structure RALb may be formed through substantially the same forming process as each other.

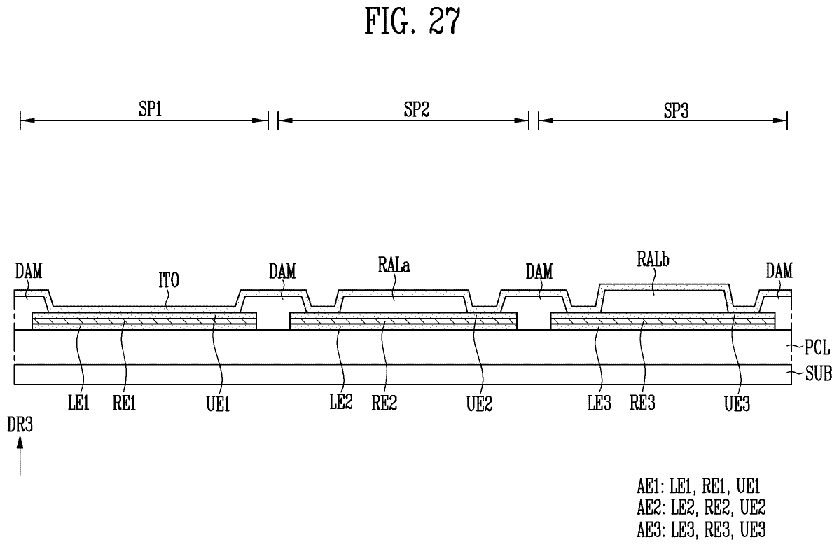

Referring to FIG. 27, a transparent electrode layer ITO may be entirely formed. The transparent electrode layer ITO may be formed by, for example, a sputtering method.

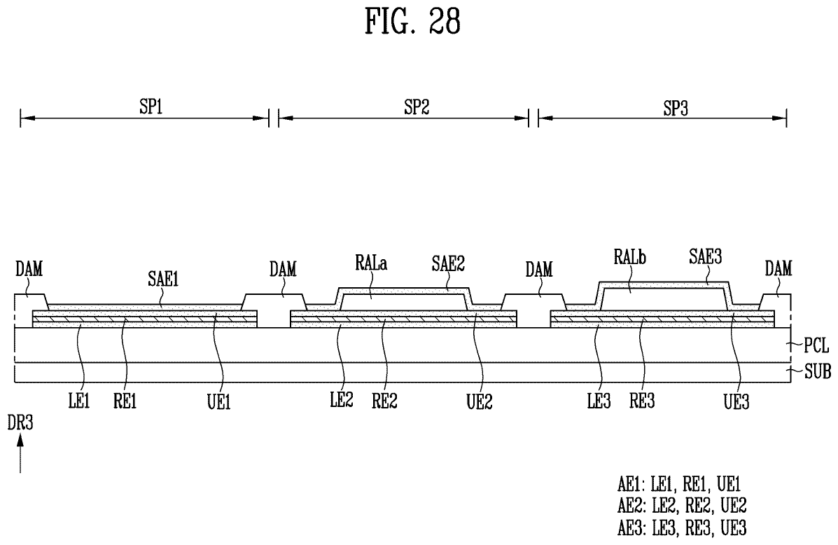

Referring to FIG. 28, the transparent electrode layer ITO may be partially etched. Accordingly, first to third sub-anode electrodes SAE1, SAE2, and SAE3 may be formed. As such, the first to third sub-anode electrodes SAE1, SAE2, and SAE3 may be formed through substantially the same forming process as each other.

Subsequently, the first common layer CML1, the light emission stack layer ESTK, the second common layer CML2, and the cathode electrode CE, which are described above with reference to FIGS. 7, 11, 15, etc., may be sequentially formed. In this process, the first common layer CML1, the light emission stack layer ESTK, the second common layer CML2, and the cathode electrode CE may be provided on the entire surface by using a blanket deposition process.

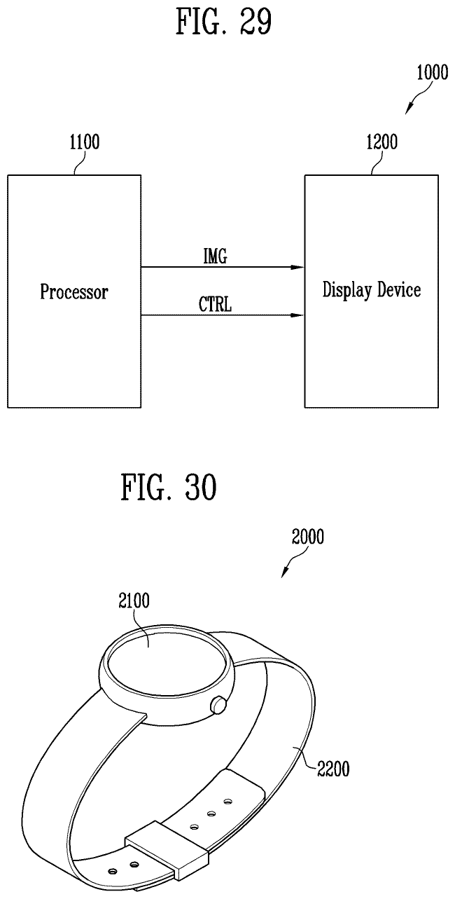

FIG. 29 is a block diagram showing a display system in accordance with an embodiment.

Referring to FIG. 29, an embodiment of a display system 1000 may include a processor 1100 and a display device 1200.

The processor 1100 may perform various tasks and calculations. In embodiments, the processor 1100 may include an application processor, a graphics processor, a microprocessor, a central processing unit (CPU), etc. The processor 1100 may be connected to other components of the display system 1000 through a bus system and control the components of the display system 1000.

The processor 1100 may transmit image data IMG and a control signal CTRL to the display device 1200. The display device 1200 may display an image based on the image data IMG and the control signal CTRL. The display device 1200 may be configured similarly to the display device DD described with reference to FIG. 1. In this case, the image data IMG and the control signal CTRL may be provided as the input image data IMG and the control signal CTRL of FIG. 1, respectively.

The display system 1000 may include a computing system that provides an image display function, such as a smart watch, a mobile phone, a smart phone, a portable computer, a tablet personal computer, a watch phone, an automotive display, smart glasses, a portable multimedia player (PMP), a navigation system, or an ultra mobile personal computer (UMPC). In addition, the display system 1000 may include at least one selected from a head mounted display (HMD), a virtual reality (VR) device, a mixed reality (MR) device, or an augmented reality (AR) device.

FIGS. 30 to 33 are perspective views showing application examples of the display system of FIG. 29.

Referring to FIG. 30, the display system 1000 of FIG. 29 may be applied to a smart watch 2000 including a display unit 2100 and a strap portion 2200.

The smart watch 2000 may be a wearable electronic device. For example, the smart watch 2000 may have a structure in which the strap portion 2200 is mounted on a user's wrist. Here, the display system 1000 and/or the display device 1200 may be applied to the display unit 2100 and may provide image data including time information to the user.

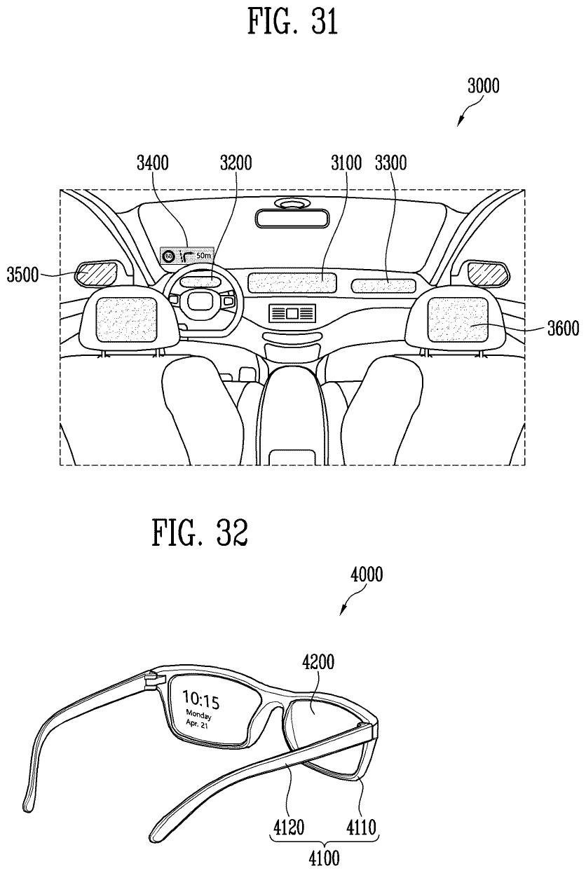

Referring to FIG. 31, the display system 1000 of FIG. 29 may be applied to an automotive display system 3000. Here, the automotive display system 3000 may include a computing system provided inside and/or outside a vehicle to provide image data.

For example, the display system 1000 and/or the display device 1200 may be applied to at least one of an infotainment panel 3100, a cluster 3200, and a co-driver display 3300, a head-up display 3400, a side mirror display 3500, and a rear-seat display 3600, which are provided in the vehicle.

Referring to FIG. 32, the display system 1000 of FIG. 29 may be applied to smart glasses 4000. The smart glasses 4000 may be a wearable electronic device that may be wearable on a user's head. For example, the smart glasses 4000 may be a wearable device for augmented reality.

The smart glasses 4000 may include a frame 4100 and a lens unit 4200. The frame 4100 may include a housing 4110 that supports the lens unit 4200 and a leg portion 4120 that is wearable on the user. The leg portion 4120 may be connected to the housing 4110 through a hinge and may be folded or unfolded relative to the housing 4110.

The frame 4100 may have a battery, a touch pad, a microphone, a camera, etc. embedded therein. In addition, the frame 4100 may include a projector that outputs light, a processor that controls light signals, etc. embedded therein.

The lens unit 4200 may include an optical member that transmits or reflects light. For example, the lens unit 4200 may include glass, transparent synthetic resin, etc.

In order for a user's eyes to recognize visual information, the lens unit 4200 may reflect an image, which is generated by an optical signal transmitted from the projector of the frame 4100, to the back surface of the lens unit 4200 (e.g., the surface facing the user's eyes). For example, the user may recognize visual information such as time and date displayed on the lens unit 4200. In such an embodiment, the projector and/or the lens unit 4200 may be a type of display device. The display device 1200 may be applied to the projector and/or the lens unit 4200.

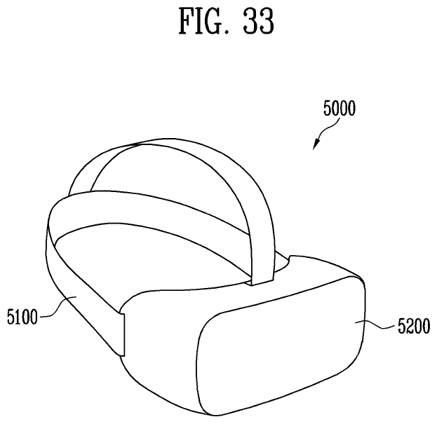

Referring to FIG. 33, the display system 1000 of FIG. 29 may be applied to an HMD device 5000.

The HMD device 5000 may be a wearable electronic device that is wearable on a user's head. For example, the HMD device 5000 may be a wearable device for virtual reality or mixed reality.

The HMD device 5000 may include a head mounted band (or a head strap) 5100 and a display device storage case 5200. The head mounted band 5100 may be connected to the display device storage case 5200. The head mounted band 5100 may include a horizontal band and/or a vertical band for fixing the HMD device 5000 to the user's head. The horizontal band may be configured to surround the sides of the user's head, and the vertical band may be configured to surround the upper portion of the user's head. However, the embodiments are not limited thereto. For example, the head mounted band 5100 may be implemented in the form of glasses frames, helmets, etc.

The display device storage case 5200 may accommodate the display system 1000 and/or the display device 1200.

A display device according to embodiments of the disclosure may include a resonance auxiliary structure disposed between an anode electrode and a sub-anode electrode. In such embodiments, the resonance auxiliary structure may serve to provide an optical distance (or a resonance distance) to effectively resonate light in a specific wavelength band. Accordingly, the display device including the resonance auxiliary structure may have high light extraction efficiency.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
first to third anode electrodes disposed on a pixel circuit layer and spaced apart from each other;
a first resonance auxiliary structure disposed on the second anode electrode and having a first thickness;
a second resonance auxiliary structure disposed on the third anode electrode and having a second thickness greater than the first thickness;
a first sub-anode electrode disposed on the first anode electrode and in electrical contact with the first anode electrode;
a second sub-anode electrode disposed on the second anode electrode to cover the first resonance auxiliary structure and in electrical contact with the second anode electrode;
a third sub-anode electrode disposed on the third anode electrode to cover the second resonance auxiliary structure and in electrical contact with the third anode electrode;
a cathode electrode disposed on the first to third anode electrodes; and
an emission stack layer disposed between the cathode electrode and the first to third sub-anode electrodes, wherein the emission stack layer comprises a first emission layer, a second emission layer, and a third emission layer, which are sequentially stacked one on another.

2. The display device of claim 1, wherein the first and second resonance auxiliary structures each include an inorganic insulating material.

3. The display device of claim 1, wherein the first to third sub-anode electrodes each include a light transmissive metal oxide.

4. The display device of claim 1, wherein the first emission layer emits light in a first wavelength band,
the second emission layer emits light in a second wavelength band which is different from the first wavelength band, and
the third emission layer emits light in a third wavelength band which is different from the first and second wavelength bands.

5. The display device of claim 1, wherein the cathode electrode includes lithium (Li)-doped silver (Ag), and
the lithium (Li)-doped silver (Ag) includes greater than about 5 mass % and less than about 50 mass % of lithium (Li), based on a total mass of the lithium (Li)-doped silver (Ag).

6. The display device of claim 1, further comprising a dam structure disposed between two adjacent anode electrodes among the first to third anode electrodes.

7. The display device of claim 6, wherein the dam structure includes a same material as materials of the first and second resonance auxiliary structures.

8. The display device of claim 6, wherein the dam structure is in contact with a top surface of each of the two adjacent anode electrodes.

9. The display device of claim 6, further comprising a first common layer disposed between the emission stack layer and the first to third sub-anode electrodes, wherein a portion of the first common layer on a top surface of the dam structure is disconnected from a portion of the first common layer on a side surface of the dam structure.

10. The display device of claim 1, wherein the emission stack layer is continuously disposed between the cathode electrode and the first to third sub-anode electrodes.

11. A display device comprising:
first and second anode electrodes disposed on a pixel circuit layer and spaced apart from each other;
a first resonance auxiliary structure disposed on the second anode electrode and having a first thickness;
a first sub-anode electrode disposed on the first anode electrode and in electrical contact with the first anode electrode;
a second sub-anode electrode disposed on the second anode electrode to cover the first resonance auxiliary structure and in electrical contact with the second anode electrode;
a cathode electrode disposed on the first and second anode electrodes; and
an emission stack layer disposed between the cathode electrode and the first and second sub-anode electrodes, wherein the emission stack layer comprises a first emission layer and a second emission layer, which are sequentially stacked one on another,
wherein the first emission layer emits first light having a wavelength in a range of about 440 nm to about 480 nm.

12. The display device of claim 11, wherein the first anode electrode comprises a first reflective electrode, and
a first optical distance between a top surface of the first reflective electrode and a bottom surface of the cathode electrode is in a range of about 700 angstroms to about 800 angstroms.

13. The display device of claim 12, wherein a first resonance distance between the top surface of the first reflective electrode and an emission center of the first emission layer is in a range of about 250 angstroms to about 300 angstroms.

14. The display device of claim 13, wherein the second emission layer is configured to emit second light having a wavelength in a range of about 500 nm to about 540 nm.

15. The display device of claim 14, wherein the first thickness is in a range of about 150 angstroms to about 350 angstroms.

16. The display device of claim 13, wherein the emission stack layer further comprises a third emission layer disposed on the second emission layer, and
the third emission layer emits third light having a wavelength in a range of about 610 nm to about 650 nm.

17. The display device of claim 16, further comprising:
a third anode electrode disposed on the pixel circuit layer and spaced apart from the first and second anode electrodes;
a second resonance auxiliary structure disposed on the third anode electrode and having a second thickness; and
a third sub-anode electrode disposed on the third anode electrode to cover the second resonance auxiliary structure and in electrical contact with the third anode electrode.

18. The display device of claim 17, wherein the second thickness is in a range of about 400 angstroms to about 600 angstroms.

19. The display device of claim 11, wherein the emission stack layer is continuously disposed on the pixel circuit layer and the first and second sub-anode electrodes.

20. The display device of claim 11, wherein the cathode electrode includes lithium (Li)-doped silver (Ag), and
the lithium (Li)-doped silver (Ag) includes greater than about 5 mass % and less than about 50 mass % of lithium (Li), based on a total mass of the lithium (Li)-doped silver (Ag).
